(19) United States
(12) Patent Application Publication
(10) Pub. No.: US 2021/0040253 A1
(43) Pub. Date: Feb. 11, 2021

(54) PHOTORESIST RESIN, PRODUCTION METHOD FOR PHOTORESIST RESIN, PHOTORESIST RESIN COMPOSITION, AND PATTERN FORMATION METHOD

(71) Applicant: DAICEL CORPORATION, Osaka-shi, Osaka (JP)

(72) Inventors: Akinori ITO, Tokyo (JP); Akira EGUCHI, Tokyo (JP)

(73) Assignee: DAICEL CORPORATION, Osaka-shi, Osaka (JP)

(21) Appl. No.: 16/964,038

(22) PCT Filed: Jan. 31, 2019
(86) PCT No.: PCT/JP2019/003515

§ 371 Date: Jul. 22, 2020

(30) Foreign Application Priority Data
Mar. 19, 2018 (JP) 2018-051755

(51) Int. Cl. C08F 220/18; G03F 7/039; G03F 7/038; C08F 220/36; C08F 220/28

(52) U.S. Cl. CPC C08F 220/1811; G03F 7/039; C08F 220/283; C08F 220/36; G03F 7/038

(57) ABSTRACT

Provided are a photoresist resin having high solubility in solvents and a method for producing the photoresist resin. Also provided are a photoresist resin composition containing the photoresist resin and a pattern formation method using the photoresist resin composition. A photoresist resin containing no cyano group at a resin end and having a molecular weight distribution (Mw/Mn) of not greater than 1.4.

### TECHNICAL FIELD

The present invention relates to a photoresist resin used for fine processing of semiconductors, a method for producing a photoresist resin, a photoresist resin composition containing the photoresist resin, and a pattern formation method using the photoresist resin composition. The present application claims priority to JP 2018-051755 filed in Japan on Mar. 19, 2018, the content of which is incorporated herein.

### BACKGROUND ART

A method typically used for producing a (meth)acrylate polymer is a radical polymerization method using a monomer ((meth)acrylate), a radical polymerization initiator, and, as necessary, a chain transfer agent. Examples of such a polymerization method known in the art include the following dropwise polymerization methods (Patent Documents 1 and 2).

(1) Method of preheating and adding dropwise a monomer

(2) Method of adding dropwise a monomer into a polymerization solvent maintained at a constant temperature

### CITATION LIST

### Patent Document

Patent Document 1: JP 2004-269855 A

Patent Document 2: JP 2004-355023 A

### SUMMARY OF INVENTION

### Technical Problem

However, in a case of the radical polymerization described above, a termination reaction, such as deactivation of a propagating radical, may occur, which causes difficulty in controlling the molecular chain length of the resulting polymer. In addition, polymers having a wide range of molecular weight distribution (in particular, polymers having a high molecular weight) have low solubility in solvents, and this may lead to the generation of foreign matter over time and the occurrence of defects during the exposure process.

Thus, an object of the present invention is to provide a photoresist resin having high solubility in solvents and a method for producing the photoresist resin.

Furthermore, another object of the present invention is to provide a photoresist resin composition containing the photoresist resin and a pattern formation method using the photoresist resin composition.

### Solution to Problem

As a result of diligent research to achieve the objects described above, the present inventors found that controlling the molecular chain length and molecular chain end of the polymer (photoresist resin) improves the solubility in solvents. The present invention was completed based on these findings.

That is, an embodiment of the present invention provides a photoresist resin containing no cyano group at a resin end and having a molecular weight distribution (Mw/Mn) of not greater than 1.4.

In the photoresist resin, a substituent at the resin end is preferably an alkyl group, an aryl group, a carboxyl group, an amino group, a group having an ester bond, a group having an ether bond, a group having a thioether bond, or a group having an amide bond.

The photoresist resin preferably contains at least one polymerization unit selected from the group consisting of polymerization units represented by Formulas (a1) to (a4) below:

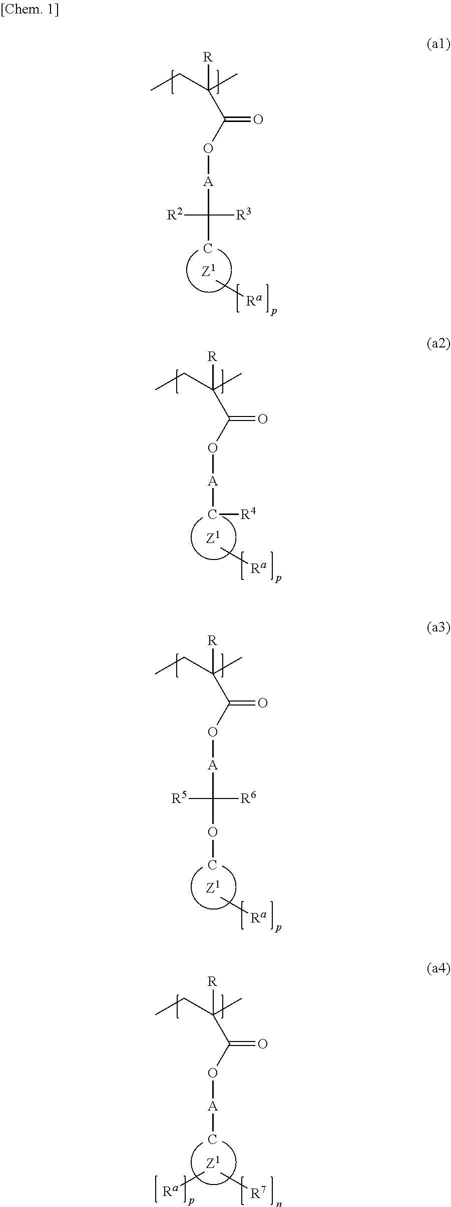

where R represents a hydrogen atom, a halogen atom, or an alkyl group that has from 1 to 6 carbon atoms and may have a hydrogen atom; A represents a single bond or a linking group; R² to R⁴ are identical or different and represent an alkyl group that has from 1 to 6 carbon atoms and may have a substituent; R² and R³ may be bonded to each other to form a ring; R⁵ and R⁶ are identical or different and represent an alkyl group that has from 1 to 6 carbon atoms and may have a hydrogen atom or a substituent; R⁷ represents a —COOR^{c} group, and R^{c} represents a tertiary hydrocarbon group that may have a substituent, a tetrahydrofuranyl group, a tetrahydropyranyl group, or an oxepanyl group; n represents an integer from 1 to 3; R^{a} represents a substituent bonded to a ring Z¹, and each R^{a} is identical or different and is an oxo group, an alkyl group, a hydroxy group that may be protected with a protecting group, a hydroxyalkyl group that may be protected with a protecting group, or a carboxy group that may be protected with a protecting group; p represents an integer from 0 to 3; and the ring Z¹ represents an alicyclic hydrocarbon ring having from 3 to 20 carbon atoms.

The photoresist resin preferably further contains at least one polymerization unit selected from the group consisting of polymerization units represented by

Formulas (b1) to (b5) below:

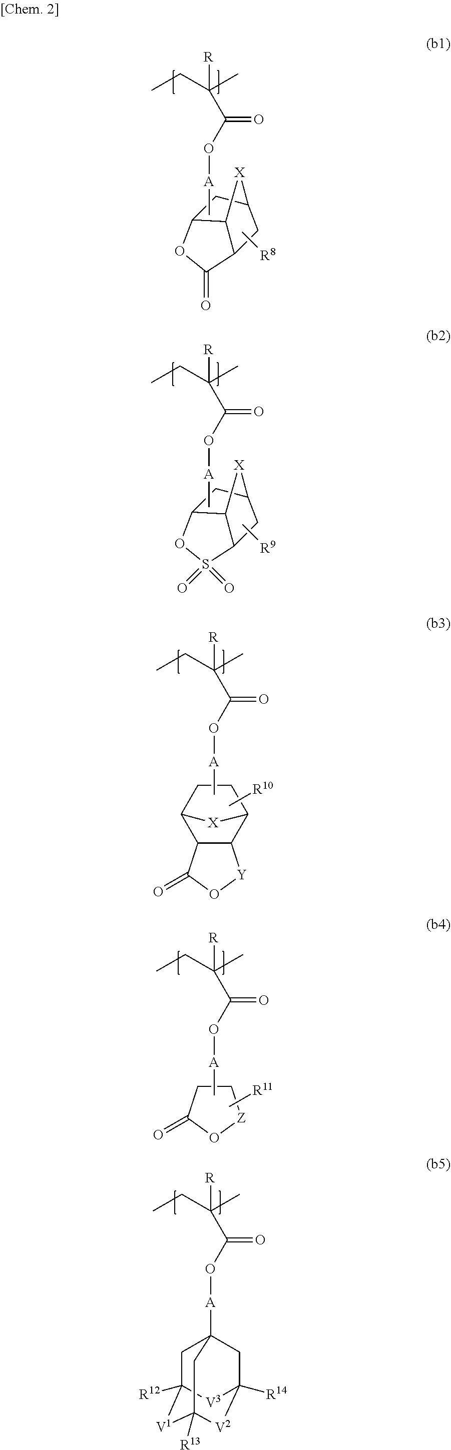

where R represents a hydrogen atom, a halogen atom, or an alkyl group that has from 1 to 6 carbon atoms and may have a hydrogen atom; A represents a single bond or a linking group; X represents no bond, a methylene group, an ethylene group, an oxygen atom, or a sulfur atom; Y represents a methylene group or a carbonyl group; Z represents a divalent organic group; V¹ to V³ are identical or different and represent —CH₂—, [—C(═O)—], or [—C(═O)—] with the proviso that at least one of V¹ to V³ is [—C(═O)—O—]; and R⁸ to R¹⁴ are identical or different and represent a hydrogen atom, a fluorine atom, an alkyl group that may have a fluorine atom, a hydroxy group that may be protected with a protecting group, a hydroxyalkyl group that may be protected with a protecting group, a carboxy group that may be protected with a protecting group, or a cyano group.

The photoresist resin preferably further contains a polymerization unit represented by Formula (c1) below:

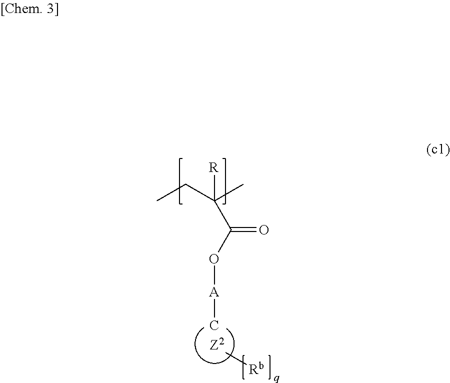

where R represents a hydrogen atom, a halogen atom, or an alkyl group that has from 1 to 6 carbon atoms and may have a hydrogen atom; A represents a single bond or a linking group; R^{b} represents a hydroxy group that may be protected with a protecting group, a hydroxyalkyl group that may be protected with a protecting group, a carboxy group that may be protected with a protecting group, or a cyano group; q represents an integer from 1 to 5; and a ring Z² represents an alicyclic hydrocarbon ring having from 6 to 20 carbon atoms.

In addition, an embodiment of the present invention provides a method for producing a photoresist resin, the method including polymerizing a monomer in the presence of a chain transfer agent containing no cyano group and containing a thiocarbonylthio group and a polymerization initiator containing no cyano group.

In the method for producing a photoresist resin, the resin end is preferably further treated in the presence of an end treatment agent containing no cyano group.

In addition, an embodiment of the present invention provides a photoresist resin composition containing at least the photoresist resin and a radiation-sensitive acid generator.

In addition, an embodiment of the present invention provides a pattern formation method including at least applying the photoresist resin composition to a substrate to form a coating film, exposing the coating film, and then dissolving the coating film with an alkali.

### Advantageous Effects of Invention

The photoresist resin according to an embodiment of the present invention and the production method according to an embodiment of the present invention can provide a photoresist resin having high solubility in solvents and excellent resist performance, and a photoresist resin composition containing the photoresist resin. In addition, use of the photoresist resin composition can form an excellent pattern.

### DESCRIPTION OF EMBODIMENTS

Photoresist resin

A photoresist resin according to an embodiment of the present invention contains no cyano group at a resin end and has a molecular weight distribution (Mw/Mn) of not greater than 1.4. The above resin end means an end of a main chain of the resin. The resin having such a structure is obtained, for example, by polymerizing a monomer constituting the photoresist resin according to an embodiment of the present invention (e.g., such as a monomer unit a, a monomer unit b, or a monomer unit c described later) in the presence of a chain transfer agent containing no cyano group and containing a thiocarbonylthio group and a polymerization initiator containing no cyano group. In addition, the resin is obtained through a treatment of the polymer obtained by the polymerization above in the presence of an end treatment agent containing no cyano group. That is, the photoresist resin according to an embodiment of the present invention is preferably a resin having at its end a substituent derived from the chain transfer agent containing no cyano group and containing a thiocarbonylthio group and a substituent derived from the polymerization initiator containing no cyano group; or a resin having at its end at least one substituent selected from the group consisting of a substituent derived from the chain transfer agent containing no cyano group and containing a thiocarbonylthio group, a substituent derived from the polymerization initiator containing no cyano group, and a substituent derived from the end treatment agent containing no cyano group.

The group other than a cyano group at the end of the photoresist resin according to an embodiment of the present invention is not particularly limited, but examples include an alkyl group, an aryl group, a carboxyl group, an amino group, a group having an ester bond, a group having an ether bond, a group having a thioether bond, or a group having an amide bond. Examples of the alkyl group include a linear alkyl group, a branched alkyl group, and a cyclic alkyl group. The number of carbon atoms in the alkyl group is not particularly limited but is, for example, preferably from 1 to 15, more preferably from 1 to 10, and even more preferably from 1 to 6. Examples of the aryl group include a monocyclic aryl group and a polycyclic (e.g., bicyclic to tetracyclic) aryl group. The number of carbon atoms in the aryl group is not particularly limited but is, for example, preferably from 6 to 15, more preferably from 6 to 10, and even more preferably 6. Examples of the group having an ester bond include a group constituted of a monovalent alkyl group and an ester bond and a group in which a monovalent alkyl group and a divalent alkyl group are bonded via an ester bond. Examples of the group having an ether bond include a group constituted of a monovalent alkyl group and an ether bond and a group in which a monovalent alkyl group and a divalent alkyl group are bonded via an ether bond. Examples of the group having a thioether bond include a group constituted of a monovalent alkyl group and a thioether bond and a group in which a monovalent alkyl group and a divalent alkyl group are bonded via a thioether bond. Examples of the group having an amide bond include a group constituted of a monovalent alkyl group and an amide bond and a group in which a monovalent alkyl group and a divalent alkyl group are bonded via an amide bond. The monovalent alkyl group and the divalent alkyl group described above are identical or different and may be a linear alkyl group, a branched alkyl group, or a cyclic alkyl group and have, for example, preferably from 1 to 10 and more preferably from 1 to 6 carbon atoms. The group having an ester bond, the group having an ether bond, the group having a thioether bond, and the group having an amide bond may have at least one group selected from the group consisting of an aryl group, a carboxyl group, and an amino group.

The photoresist resin according to an embodiment of the present invention may have a group (which may be referred to as an “acid-decomposable group”) of which portion is eliminated by an action of an acid to form a polar group. As a result, the photoresist resin according to an embodiment of the present invention has increased polarity due to the action of the acid and has increased solubility in an alkaline developer.

Examples of the polar group include acidic groups, such as phenolic hydroxyl groups, carboxy groups, fluorinated alcohol groups (preferably a hexafluoroisopropanol group), sulfonic acid groups, sulfonamide groups, sulfonylimide groups, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups; and alcoholic hydroxyl groups. Among them, carboxy groups, fluorinated alcohol groups (preferably a hexafluoroisopropanol group), and sulfonate groups are preferred.

The acid-decomposable group is preferably a group in which a hydrogen atom of the polar group is substituted with a group to be eliminated with an acid. Examples of the acid-decomposable group include —C(R^{I})(R^{II})(R^{III}) and —C(R^{IV})(R^{V})(OR^{VI}). In the formula, R^{I} to R^{III}, and R^{VI} each independently represent an alkyl group, a cycloalkyl group, an aryl group, an aralkyl group, or an alkenyl group. R^{IV} and R^{V} each independently represent a hydrogen atom, an alkyl group, a cycloalkyl group, an aryl group, an aralkyl group, or an alkenyl group. At least two groups of R^{I} to R^{III} may be bonded to each other to form a ring. In addition, R^{IV} and R^{V} may be bonded to each other to form a ring.

The number of carbon atoms in the acid-decomposable group is not particularly limited but is preferably not less than 4 and more preferably not less than 5. The upper limit of the number of carbon atoms is not particularly limited but is preferably 20.

The alkyl group of the RI to RvI is preferably an alkyl group having from 1 to 8 carbon atoms, and examples include a methyl group, an ethyl group, a propyl group, an n-butyl group, an s-butyl group, a t-butyl group, a hexyl group, and an octyl group.

The cycloalkyl group of the R^{I} to R^{VI} may be a monocyclic hydrocarbon group or a polycyclic (bridged cyclic) hydrocarbon group. The monocyclic hydrocarbon group is preferably a cycloalkyl group having from 3 to 8 carbon atoms, and examples include a cyclopropyl group, a cyclobutyl group, a cyclopentyl group, a cyclohexyl group, and a cyclooctyl group. The polycyclic hydrocarbon group is preferably a cycloalkyl group having from 6 to 20 carbon atoms, and examples include an adamantyl group, a norbornyl group, an isoboronyl group, a camphanyl group, a dicyclopentyl group, an a-pinel group, a tricyclodecanyl group, a tetracyclododecyl group, and an androstanyl group. At least one carbon atom in the cycloalkyl group may be substituted with a hetero atom, such as an oxygen atom.

The aryl group of the R^{I} to R^{VI} is preferably an aryl group having from 6 to 14 carbon atoms, and examples include a phenyl group, a naphthyl group, and an anthryl group.

The aralkyl group of the R^{I} to R^{VI} is preferably an aralkyl group having from 7 to 12 carbon atoms, and examples include a benzyl group, a phenethyl group, and a naphthylmethyl group.

The alkenyl group of the R^{I} to R^{VI} is preferably an alkenyl group having from 2 to 8 carbon atoms, and examples include a vinyl group, an allyl group, a butenyl group, and a cyclohexenyl group.

The ring formed by the at least two groups of the R^{I} to R^{III} bonded to each other and the ring formed by the R^{IV} and R^{V} bonded to each other are preferably a cycloalkane ring. Examples of the cycloalkane ring include monocyclic cycloalkane rings, such as a cyclopropane ring, a cyclobutane ring, a cyclopentane ring, and a cyclohexane ring; and polycyclic cycloalkane rings, such as a norbornane ring, a tricyclodecane ring, a tetracyclododecane ring, and an adamantane ring.

The alkyl group, the cycloalkyl group, the aryl group, the aralkyl group, the alkenyl group, and the cycloalkane ring in the R^{I} to R^{VI} may each have a substituent.

The acid-decomposable group is preferably, among others, a t-butyl group, a t-amyl group, and groups represented by Formulas (I) to (IV) below.

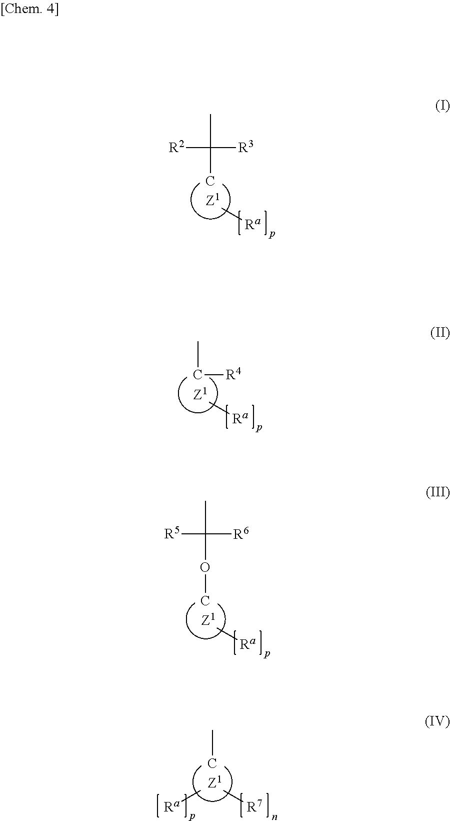

R² to R⁷, R^{a}, n, p, and a ring Z¹ in Formulas (I) to (IV) above are respectively the same as R² to R⁷, R^{a}, n, p, and the ring Z¹ in Formulas (a1) to (a4) described later.

The acid-decomposable group may be provided via a spacer. The spacer is the same as a linking group exemplified and described as A in Formula (1) described later.

The photoresist resin according to an embodiment of the present invention preferably contains an acid-decomposable group as a polymerization unit having an acid-decomposable group. Examples of the polymerization unit having such an acid-decomposable group include a polymerization unit represented by Formula (1) below. That is, the photoresist resin according to an embodiment of the present invention is preferably an acrylic-based resin.

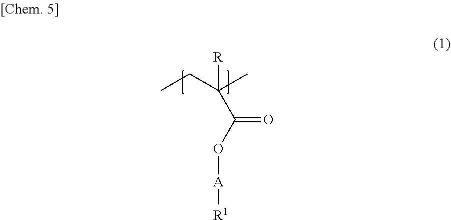

In Formula (1) above, R^{I} represents the acid-decomposable group. In addition, in Formula (1) above, R represents a hydrogen atom, a halogen atom, or an alkyl group that has from 1 to 6 carbon atoms and may have a halogen atom. Examples of the halogen atom include a chlorine atom, a bromine atom, and an iodine atom. Examples of the alkyl group having from 1 to 6 carbon atoms include a methyl group, an ethyl group, a propyl group, an isopropyl group, an n-butyl group, an isobutyl group, an s-butyl group, a t-butyl group, a pentyl group, an isoamyl group, an s-amyl group, a t-amyl group, and a hexyl group. Examples of the alkyl group having from 1 to 6 carbon atoms and having a halogen atom include a group (halo (C₁₋₆) alkyl group) in which one or more of the hydrogen atoms constituting the alkyl group are substituted with halogen atoms, such as trifluoromethyl and 2,2,2-trifluoroethyl groups.

In Formula (1) above, A represents a single bond or a linking group. Examples of the linking group include a carbonyl group (—C(═O)—), an ether bond (—O—), an ester bond (—C(═O)—O—), an amide bond (—C(═O)—NH—), a carbonate bond (—O—C(═O)—O—), a group in which a plurality of these groups is linked, and a group in which an alkylene group and these groups are bonded. Examples of the alkylene group include linear or branched alkylene groups, such as a methylene group, a methylmethylene group, a dimethylmethylene group, an ethylene group, a propylene group, and a trimethylene group; and divalent alicyclic hydrocarbon groups (in particular, divalent cycloalkylene groups), such as a 1,2-cyclopentylene group, a 1,3-cyclopentylene group, a cyclopentylidene group, a 1,2-cyclohexylene group, a 1,3-cyclohexylene group, a 1,4-cyclohexylene group, and a cyclohexylidene group.

Among the polymerization units represented by Formula (1) above, the photoresist resin according to an embodiment of the present invention preferably includes at least one polymerization unit selected from the group consisting of polymerization units represented by Formulas (a1) to (a4) below. The “at least one polymerization unit selected from the group consisting of polymerization units represented by Formulas (a1) to (a4)” may be referred to as a “monomer unit a”.

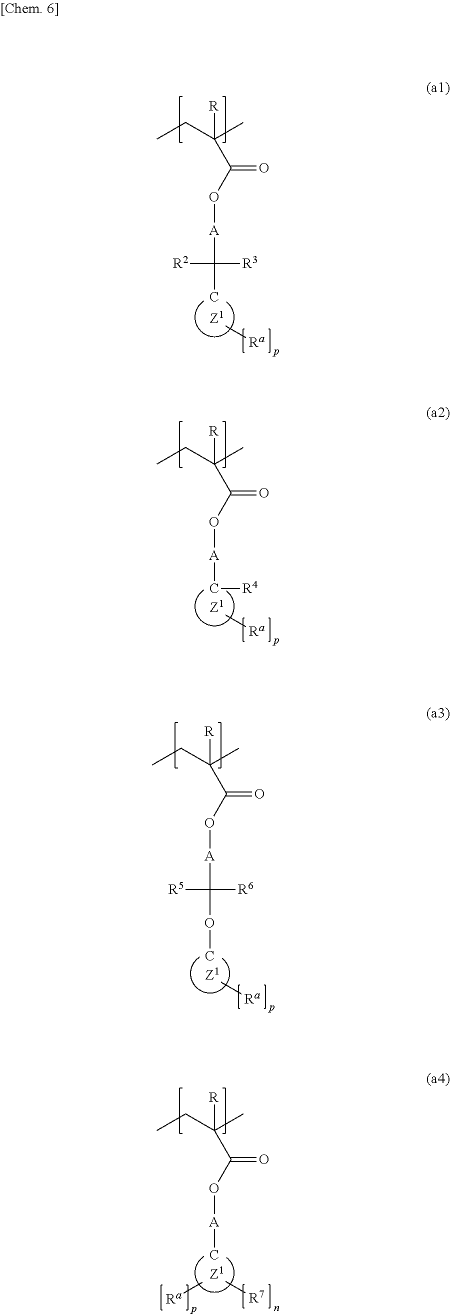

In the polymerization units represented by Formulas (a1) to (a4) above, similarly to the R in Formula (1) above, R represents a hydrogen atom, a halogen atom, or an alkyl group that has from 1 to 6 carbon atoms and may have a halogen atom, and A represents a single bond or a linking group. The A in Formulas (a1) to (a4) above is preferably, among others, a single bond, and a group in which an alkylene group and a carbonyloxy group are bonded (an alkylene-carbonyloxy group). R² to R⁴ are identical or different and represent an alkyl group that has from 1 to 6 carbon atoms and may have a substituent. R² and R³ may be bonded to each other to form a ring. R⁵ and R⁶ are identical or different and represent an alkyl group that has from 1 to 6 carbon atoms and may have a hydrogen atom or a substituent. R⁷ represents a —COORS group, and the RC represents a tertiary hydrocarbon group that may have a substituent, a tetrahydrofuranyl group, a tetrahydropyranyl group, or an oxepanyl group. n represents an integer from 1 to 3. When the n is 2 or 3, two or three R⁷s may be identical or different. R^{a} represents a substituent bonded to a ring Z¹, and each R^{a} is identical or different and is an oxo group, an alkyl group, a hydroxy group that may be protected with a protecting group, a hydroxyalkyl group that may be protected with a protecting group, or a carboxy group that may be protected with a protecting group. p represents an integer from 0 to 3. The ring Z¹ represents an alicyclic hydrocarbon ring having from 3 to 20 carbon atoms. When the p is 2 or 3, two or three R^{a}s may be identical or different.

Examples of the alkyl group in the R^{a} include alkyl groups having from 1 to 6 carbon atoms, such as a methyl group, an ethyl group, a propyl group, an isopropyl group, an n-butyl group, an s-butyl group, a t-butyl group, a pentyl group, an isoamyl group, an s-amyl group, a t-amyl group, and a n-hexyl group.

Examples of the hydroxyalkyl group in the R^{a} include hydroxy C₁₋₆ alkyl groups, such as a hydroxymethyl group, a 2-hydroxyethyl group, a 1-hydroxyethyl group, a 3-hydroxypropyl group, a 2-hydroxypropyl group, a 4-hydroxybutyl group, and a 6-hydroxyhexyl group.

Examples of the protecting group that the hydroxy group and the hydroxyalkyl group in the R^{a} may have include C₁₋₄ alkyl groups, such as a methyl group, an ethyl group, and a t-butyl group; a group that forms an acetal bond together with the oxygen atom constituting the hydroxy group (e.g., C₁₋₄ alkyl-O—C₁₋₄ alkyl groups, such as a methoxymethyl group); a group that forms an ester bond together with the oxygen atom constituting the hydroxy group (e.g., such as an acetyl group and a benzoyl group).

Examples of the protecting group of the carboxy group in the R^{a} include C₁₋₆ alkyl groups, such as a methyl group, an ethyl group, a propyl group, an isopropyl group, an n-butyl group, an s-butyl group, a t-butyl group, a pentyl group, an isoamyl group, an s-amyl group, a t-amyl group, and a hexyl group; a 2-tetrahydrofuranyl group; a 2-tetrahydropyranyl group; and a 2-oxepanyl group.

Examples of the alkyl group having from 1 to 6 carbon atoms in the R² to R⁶ include linear or branched alkyl groups, such as a methyl group, an ethyl group, a propyl group, an isopropyl group, an n-butyl group, an isobutyl group, an s-butyl group, a t-butyl group, a pentyl group, an isoamyl group, an s-amyl group, a t-amyl group, and a hexyl group. In an embodiment of the present invention, among them, C₁₋₄ alkyl groups are preferred, C₁₋₃ alkyl groups are more preferred, and C₁₋₂ alkyl groups are even more preferred.

Examples of the substituent that the alkyl group having from 1 to 6 carbon atoms in the R² to R⁶ may have include a halogen atom, a hydroxy group, a substituted hydroxy group (e.g., such as a C₁₋₄ alkoxy group, such as a methoxy group, an ethoxy group, and a propoxy group), and a cyano group. Examples of the alkyl group having from 1 to 6 carbon atoms and having a substituent include a halo (C₁₋₆) alkyl group in which one or more of hydrogen atoms constituting the alkyl group are substituted with the halogen atoms, such as a trifluoromethyl group and a 2,2,2-trifluoroethyl group; a hydroxymethyl group, a 2-hydroxyethyl group, a methoxymethyl group, a 2-methoxyethyl group, an ethoxymethyl group, a 2-ethoxyethyl group, a cyanomethyl group, and a 2-cyanoethyl group.

In a case where the R² and R³ are bonded to each other to form a ring, examples of the ring include alicyclic hydrocarbon rings that have from 3 to 12 carbon atoms and may have a substituent.

Examples of the tertiary hydrocarbon group in the R^{c} include a t-butyl group and a t-amyl group.

Examples of the substituent that the tertiary hydrocarbon group in the R^{c} may have include a halogen atom, a hydroxy group, a substituted hydroxy group (e.g., such as a C₁₋₄ alkoxy group, such as a methoxy group, an ethoxy group, and a propoxy group), and a cyano group.

Examples of the alicyclic hydrocarbon ring having from 3 to 20 carbon atoms in the ring Z¹ include monocyclic alicyclic hydrocarbon rings, such as approximately 3- to 20-membered (preferably 3- to 15-membered and particularly preferably 5- to 12-membered) cycloalkane rings (such as a cyclopropane ring, a cyclobutane ring, a cyclopentane ring, a cyclohexane ring, and a cyclooctane ring) and approximately 3- to 20-membered (preferably 3- to 15-membered and particularly preferably 5- to 10-membered) cycloalkene rings (such as a cyclopropene ring, a cyclobutene ring, a cyclopentene ring, and a cyclohexene ring); an adamantane ring; rings containing a norbornane ring or a norbornene ring, such as a norbornane ring, a norbornene ring, a bornane ring, an isobornane ring, a tricyclo[5.2.1.0^{2,6}]decane ring, and a tetracyclo[4.4.0.1^{2,5}.1^{7,10}]dodecane ring; a ring in which a polycyclic aromatic fused ring is hydrogenated (preferably a fully hydrogenated ring), such as a perhydroindene ring, a decalin ring (perhydronaphthalene ring), a perhydrofluorene ring (tricyclo[7.4.0.0^{3,8}]tridecane ring), and a perhydroanthracene ring; approximately from bicyclic to hexacyclic bridged hydrocarbon rings, such as bridged hydrocarbon rings of a bicyclic system, tricyclic system, tetracyclic system, etc. (e.g., bridged hydrocarbon rings having approximately from 6 to 20 carbon atoms), such as a tricyclo[4.2.2.1^{2,5}]undecane ring.

Specific examples of the monomer unit a include monomer units represented by formulas below. In the monomer units represented by the formulas below, R^{d} represents a methyl group or a hydrogen atom, and R^{e} represents a methyl group or a hydrogen atom. In addition, the bonding position of the R^{e} to the alicyclic hydrocarbon ring is not particularly limited, and one or a plurality of R^{e}s may be bonded to any carbon atom of the carbon atoms constituting the alicyclic hydrocarbon ring. When the monomer unit represented by the formulas below includes two or more R^{e}s, the two or more R^{e}s may be identical or different. The monomer unit a can be introduced into the photoresist resin by subjecting the corresponding unsaturated carboxylic ester to polymerization.

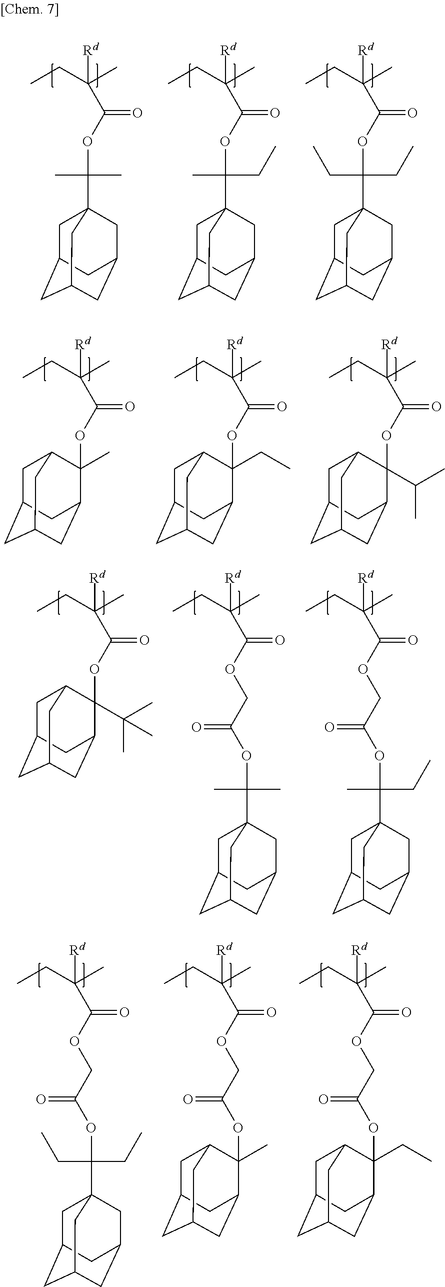

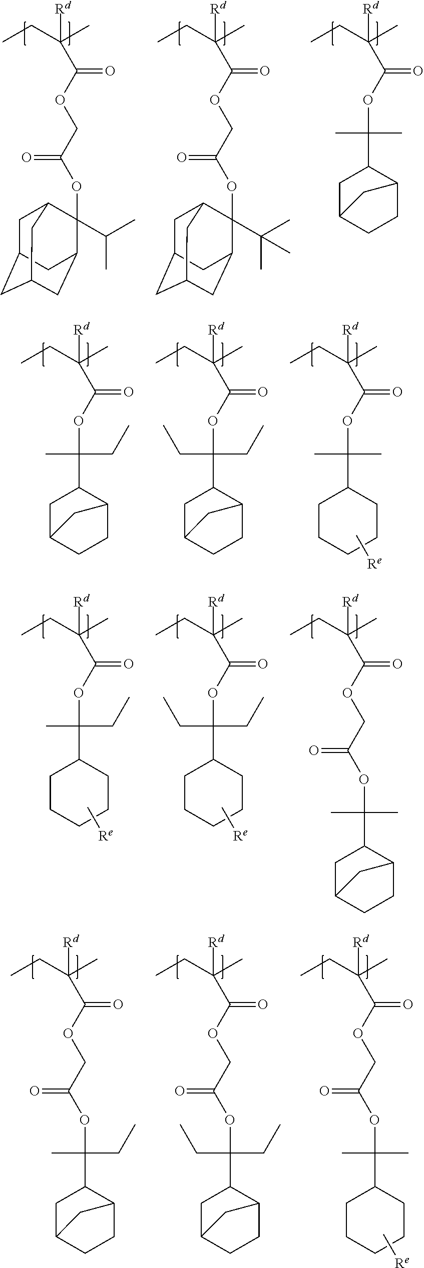

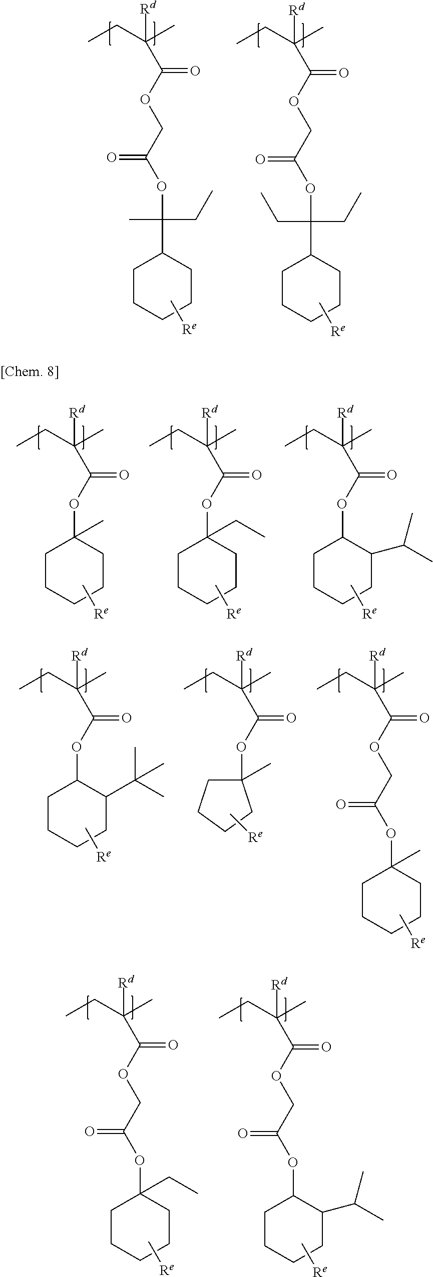

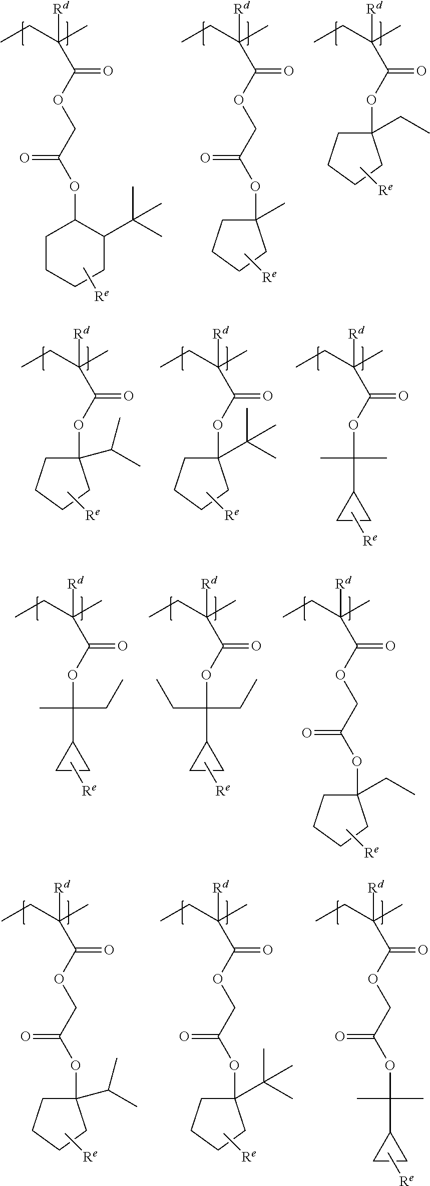

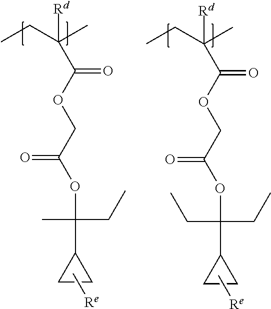

In addition to the polymerization unit represented by the monomer unit a, a polymerization unit (excluding, however, polymerization units corresponding to a monomer unit b described later) corresponding to an unsaturated carboxylic ester containing a lactone ring or the like can also be used as the polymerization unit represented by Formula (1), the unsaturated carboxylic ester having the oxygen atom constituting the ester bond bonded to the β-position of the lactone ring and at least one hydrogen atom at the α-position of the lactone ring.

Only one polymerization unit represented by Formula (1) above may be used or two or more may be used in combination. The polymerization units represented by Formula (1) above preferably includes at least one polymerization unit selected from the group consisting of polymerization units represented by Formulas (a1) to (a4) above. In addition, at least one polymerization unit represented by Formula (1) above and selected from the group consisting of polymerization units represented by Formulas (a1) to (a4) above may be used in combination with a polymerization unit represented by Formula (1) above (another polymerization unit represented by Formula (1)) other than the at least one polymerization unit selected from the group consisting of polymerization units represented by Formulas (a1) to (a4) above. The other polymerization unit represented by Formula (1) is preferably a polymerization unit represented by Formula (1) where the R¹ is a group having a tertiary hydrocarbon group (e.g., such as a t-butyl group and a t-amyl group).

In addition, the photoresist resin according to an embodiment of the present invention preferably contains an alicyclic skeleton having at least [—C(═O)—O—], [—S(═O)₂—O—], or [—C(═O)—O—C(═O)—]. The alicyclic skeleton contained in the photoresist resin can impart a higher substrate adhesion and etching resistance to the photoresist resin. The photoresist resin according to an embodiment of the present invention preferably contains the alicyclic skeleton as a polymerization unit having the alicyclic skeleton. The polymerization unit containing the alicyclic skeleton having at least [—C(═O)—O—], [—S(═O)₂—O—], or [—C(═O)—O—C(═O)—] may be referred to as a “monomer unit b”.

The monomer unit b contains, among others, preferably at least one polymerization unit selected from the group consisting of polymerization units represented by Formulas (b1) to (b5) below. In Formulas (b1) to (b5) below, R represents a hydrogen atom, a halogen atom, or an alkyl group that has from 1 to 6 carbon atoms and may have a halogen atom, and A represents a single bond or a linking group. X represents no bond, a methylene group, an ethylene group, an oxygen atom, or a sulfur atom. Y represents a methylene group or a carbonyl group. Z represents a divalent organic group (e.g., such as an alkylene group exemplified and described as an alkylene group that may be contained in the A in the polymerization units represented by Formulas (a1) to (a4) (in particular, a linear alkylene group having from 1 to 3 carbon atoms)). V¹ to V³ are identical or different and represent —CH₂—, —C(═O)—, or [—C(═O)—O—] with the proviso that at least one of the V¹ to V³ is [—C(═O)—O—]. R⁸ to R¹⁴ are identical or different and represent a hydrogen atom, a fluorine atom, an alkyl group that may have a fluorine atom, a hydroxy group that may be protected with a protecting group, a hydroxyalkyl group that may be protected with a protecting group, a carboxy group that may be protected with a protecting group, or a cyano group.

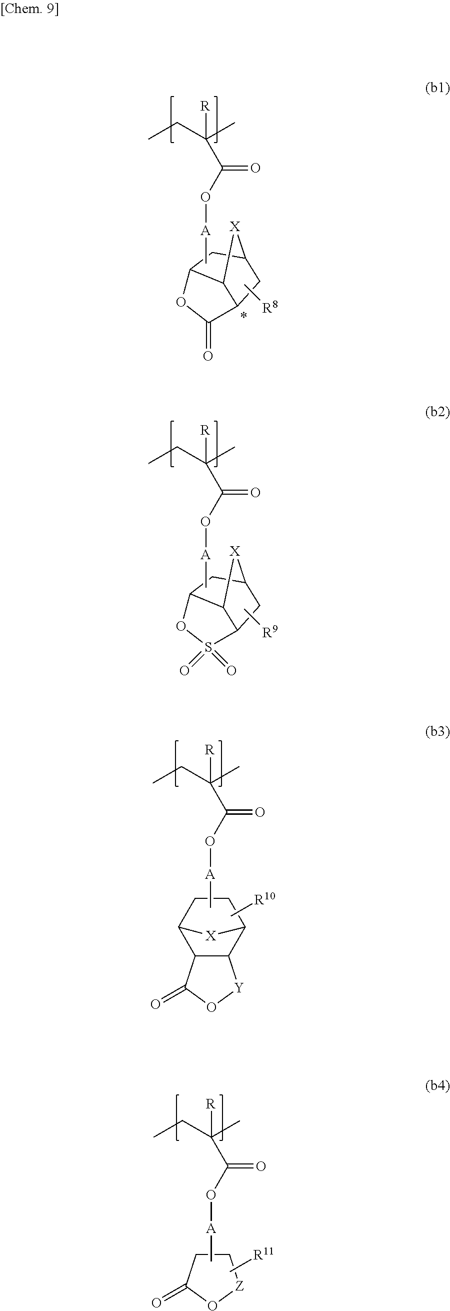

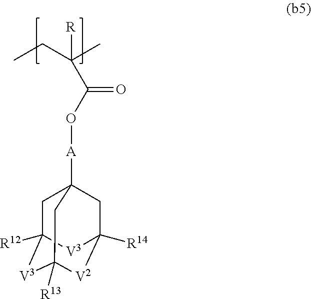

Examples of the R and A in the polymerization units represented by Formulas (b1) to (b5) include examples similar to those for the R and A in the polymerization units represented by Formulas (a1) to (a4). In addition, for the R⁸ to R¹⁴ in the polymerization units represented by Formulas (b1) to (b5), examples of the alkyl group, hydroxy group that may be protected with a protecting group, hydroxyalkyl group that may be protected with a protecting group, and carboxy group that may be protected with a protecting group include examples similar to those for the R^{a} in the polymerization units represented by Formulas (a1) to (a4).

Examples of the alkyl group having a fluorine atom in the R⁸ to R¹⁴ include a group (fluoro (C₁₋₆) alkyl group) in which one or more of the hydrogen atoms constituting the alkyl group are substituted with fluorine atoms, such as a trifluoromethyl group and a 2,2,2-trifluoroethyl group.

The polymerization units represented by Formulas (b1) to (b4) above may have one or more R⁸s to R¹¹s each and have preferably from 1 to 3 each. In addition, when the polymerization units represented by Formulas (b1) to (b4) above have two or more R⁸s to R¹¹s each, the two or more R⁸s to R¹¹s each may be identical or different.

Among the monomer units b, preferred are a polymerization unit represented by Formula (b1) where the R⁸ is an electron-withdrawing group, such as a cyano group, a group having an amide group, a group having an imide group, or a fluoro (C₁₋₆) alkyl group; a polymerization unit represented by Formula (b2); a polymerization unit represented by Formula (b3) where the Y is a carbonyl group; a polymerization unit represented by Formula (b4); and a polymerization unit represented by Formula (b5), in terms of being able to impart excellent substrate adhesion and etching resistance to the photoresist resin, having excellent solubility in an alkaline developer, and being able to form a fine pattern with high precision.

In Formula (b1) above, when R⁸ is an electron-withdrawing group, such as a cyano group, a group having an amide group, a group having an imide group, or a fluoro (C₁₋₆) alkyl group, the R⁸ is particularly preferably at least bonded to a carbon atom marked with * in Formula (b1).

Specific examples of the monomer unit b include polymerization units represented by formulas below. In the monomer units represented by the formulas below, R^{d} represents a methyl group or a hydrogen atom. The monomer unit b can be introduced into the photoresist resin by subjecting the corresponding unsaturated carboxylic ester to polymerization.

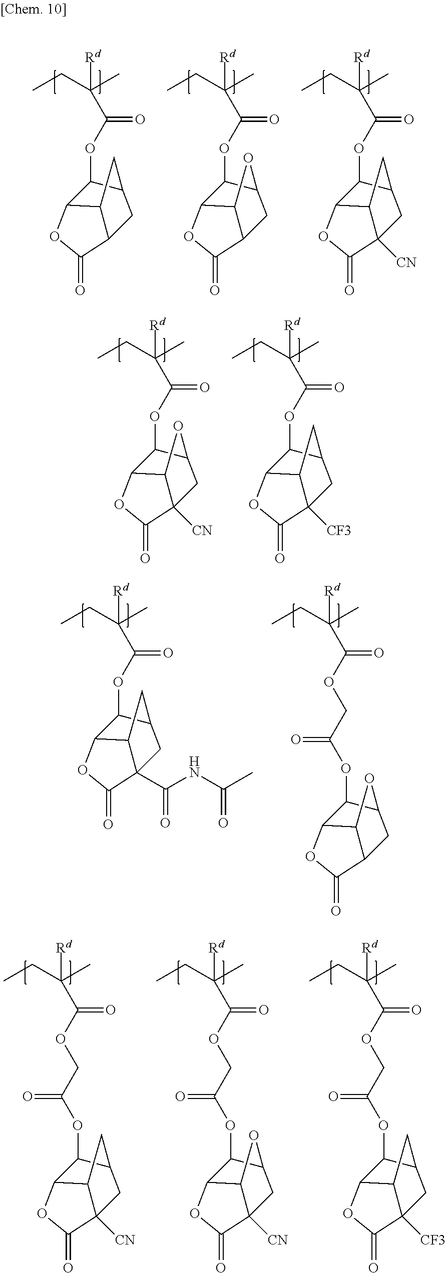

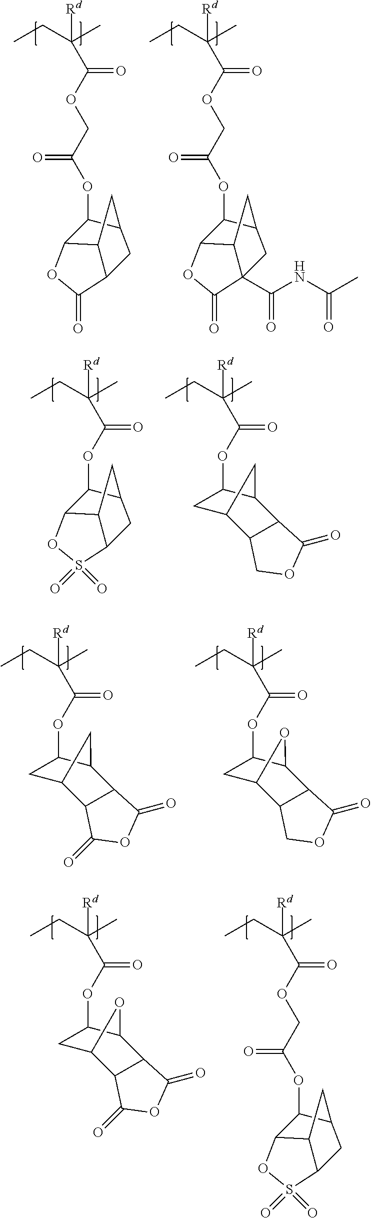

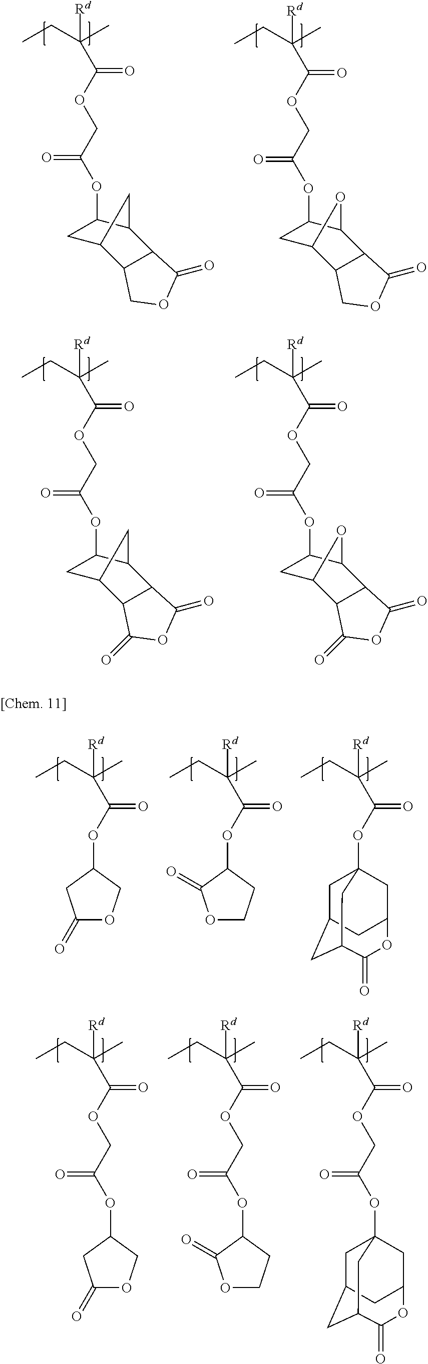

The photoresist resin according to an embodiment of the present invention may further have a monomer unit c. The monomer unit c is a polymerization unit represented by Formula (c1) below. The monomer unit c as a polymerization unit included in the photoresist resin according to an embodiment of the present invention can impart higher transparency and etching resistance to the photoresist resin. In the formula, R represents a hydrogen atom, a halogen atom, or an alkyl group that has from 1 to 6 carbon atoms and may have a halogen atom. A represents a single bond or a linking group. R^{b} represents a hydroxy group that may be protected with a protecting group, a hydroxyalkyl group that may be protected with a protecting group, a carboxy group that may be protected with a protecting group, or a cyano group, and among them, a hydroxy group and a cyano group are preferred. q represents an integer from 1 to 5. A ring Z² represents an alicyclic hydrocarbon ring having from 6 to 20 carbon atoms. When the q is an integer from 2 to 5, two to five R^{b}s may be identical or different.

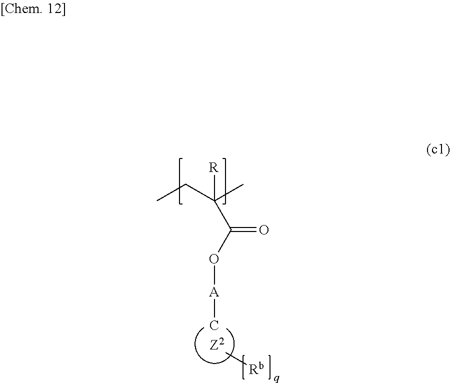

Examples of the R and A in the polymerization unit represented by Formula (c1) include examples similar to those for the R and A in the polymerization units represented by Formulas (a1) to (a4). In addition, for the R^{b} in the polymerization unit represented by Formula (c1), examples of the hydroxy group that may be protected with a protecting group, the hydroxyalkyl group that may be protected with a protecting group, and the carboxy group that may be protected with a protecting group include examples similar to those for the R^{a} in the polymerization units represented by Formulas (a1) to (a4).

The ring Z² in the polymerization unit represented by Formula (cl) represents an alicyclic hydrocarbon ring having from 6 to 20 carbon atoms, and examples include monocyclic alicyclic hydrocarbon rings, such as approximately 6- to 20-membered (preferably 6- to 15-membered and particularly preferably 6- to 12-membered) cycloalkane rings (such as a cyclohexane ring and a cyclooctane ring) and approximately 6- to 20-membered (preferably 6- to 15-membered and particularly preferably 6- to 10-membered) cycloalkene rings (such as a cyclohexene ring); an adamantane ring; rings containing a norbomane ring or a norbornene ring, such as a norbornane ring, a norbornene ring, a bornane ring, an isobornane ring, a tricyclo[5.2.1.0^{2,6}]decane ring, and a tetracyclo[4.4.0.1^{2,5}.1^{7,10}]dodecane ring; a ring in which a polycyclic aromatic fused ring is hydrogenated (preferably a fully hydrogenated ring), such as a perhydroindene ring, a decalin ring (perhydronaphthalene ring), a perhydrofluorene ring (tricyclo[7.4.0.0^{3,8}]tridecane ring), and a perhydroanthracene ring; approximately from bicyclic to hexacyclic bridged hydrocarbon rings, such as bridged hydrocarbon rings of a bicyclic system, tricyclic system, tetracyclic system, etc. (e.g., bridged hydrocarbon rings having approximately from 6 to 20 carbon atoms), such as a tricyclo[4.2.2.1^{2,5}]undecane ring. Among them, the ring Z² is preferably a ring containing a norbornane ring or a norbornene ring; and an adamantane ring.

Specific examples of the monomer unit c include polymerization units represented by formulas below. In the polymerization unit represented by formulas below, R^{d} represents a methyl group or a hydrogen atom. The monomer unit c can be introduced into the photoresist resin by subjecting the corresponding unsaturated carboxylic ester to polymerization.

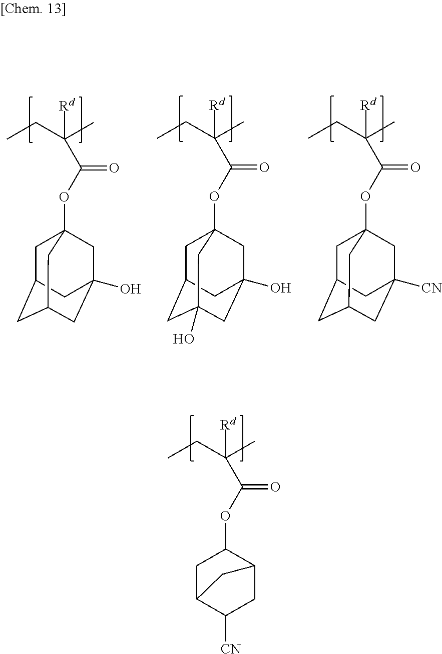

The photoresist resin according to an embodiment of the present invention preferably has at least the monomer unit a and the monomer unit b and more preferably has at least the monomer unit a, the monomer unit b, and the monomer unit c. In this case, in the photoresist resin according to an embodiment of the present invention, the content of the monomer unit a is, for example, from 3 to 90 mol %, preferably from 5 to 80 mol %, more preferably from 8 to 70 mol %, and even more preferably from 10 to 60 mol % relative to the total amount of the monomer units (polymerization units) constituting the photoresist resin. In addition, the content of the monomer unit b is, for example, from 5 to 95 mol %, preferably from 10 to 90 mol %, more preferably from 20 to 85 mol %, and even more preferably from 30 to 80 mol % relative to the total amount of the monomer units constituting the photoresist resin. Furthermore, the content of the monomer unit c when the resin according to the present invention contains the monomer unit c is, for example, from 0 to 40 mol %, preferably from 1 to 30 mol %, and more preferably from 3 to 25 mol % relative to the total amount of the monomer units constituting the photoresist resin.

In addition, the weight average molecular weight (Mw) of the photoresist resin according to an embodiment of the present invention is, for example, from 1000 to 50000, preferably from 2000 to 20000, and particularly preferably from 3000 to 15000. The molecular weight distribution (ratio of the weight average molecular weight and the number average molecular weight: Mw/Mn) of the photoresist resin according to an embodiment of the present invention is not greater than 1.4 and not particularly limited but is, for example, from 1.0 to 1.39 and preferably from 1.0 to 1.38. In the present specification, the weight average molecular weight (Mw) and the number average molecular weight (Mn) can be measured, for example, by GPC using polystyrene as a standard material.

The acid value of the photoresist resin according to an embodiment of the present invention is not particularly limited but is, for example, not greater than 0.10 mmol/g, preferably not greater than 0.05 mmol/g, and more preferably not greater than 0.03 mmol/g. With the acid value within the above range, the acid-decomposable group in the photoresist resin is not eliminated but protected, and thus the photoresist resin tends to have excellent resist performance and good stability over time. The lower limit of the acid value may be 0 mmol/g.

### Method for Producing Photoresist Resin According to Embodiment of Present Invention

A method for producing a photoresist resin according to an embodiment of the present invention includes polymerizing a monomer in the presence of a chain transfer agent containing no cyano group and containing a thiocarbonylthio group and a polymerization initiator containing no cyano group (which may be hereinafter referred to as the “polymerization”). The method for producing a photoresist resin according to an embodiment of the present invention may further include treating a resin end in the presence of an end treatment agent containing no cyano group (which may be hereinafter referred to as the “treatment”).

### Polymerization

The polymerization is to polymerize a monomer in the presence of the chain transfer agent and the polymerization initiator and is not particularly limited, but examples include utilizing a method of polymerizing a monomer by adding a monomer or a solution containing a monomer dropwise in the presence of the chain transfer agent and the polymerization initiator (a dropwise polymerization method).

Specifically, examples of the dropwise polymerization method include (1) adding dropwise a solution containing the chain transfer agent, the polymerization initiator, and the monomer, (2) adding dropwise a solution containing the chain transfer agent and the monomer to a solution containing the polymerization initiator, (3) adding dropwise a solution containing the polymerization initiator and the monomer to a solution containing the chain transfer agent, and (4) adding dropwise a monomer or a solution containing a monomer to a solution containing the polymerization initiator and the chain transfer agent.

The polymerization is particularly preferably adding dropwise a solution containing a monomer to a solution containing the chain transfer agent and the polymerization initiator. The solution to be added dropwise and the solution to receive the dropwise addition may contain a basic compound with a pKb of not higher than 10 in addition to the chain transfer agent and the polymerization initiator. A well-known monomer having radical polymerizability can be used as the monomer, and examples include monomers corresponding to the polymerization units exemplified for the photoresist resin according to an embodiment of the present invention.

The polymerization is preferably performed in the presence of a basic compound having a pKb of not higher than 10 (which may be hereinafter referred to as the “basic compound A”). If the chain transfer agent or the solvent has high acidity, the acid-decomposable group in the photoresist resin having the acid-decomposable group would be decomposed in the polymerization, and the produced photoresist resin would have poor stability over time. The use of the basic compound A prevents the elimination of the acid-decomposable group in the resin due to the elimination reaction by acid during the polymerization and can provide a photoresist resin having good stability over time while having excellent resist performance.

Examples of the chain transfer agent containing no cyano group and containing a thiocarbonylthio group includes well-known or commonly used chain transfer agents used in radical polymerization. Examples of the chain transfer agent include didithiobenzoates, such as 2-phenyl-2-propyl benzodithioate, 1-(methoxycarbonyl)ethyl benzodithioate, benzyl benzodithioate, ethyl-2-methyl-2-(phenylthiocarbonylthio)propionate, methyl-2-phenyl-2-(phenylcarbonothioylthio)acetate, ethyl-2-(phenylcarbonothioylthio)propionate, and bis(thiobenzoyl)disulfide; trithiocarbonates, such as 2-(dodecylthiocarbonylthioylthio)propionic acid, 2-(dodecylthiocarbonylthioylthio)-2-methylpropionic acid, methyl-2-(dodecylthiocarbonylthioylthio)-2-methylpropionate, 2-(dodecylthiocarbonylthioylthio)-2-methylpropionic acid N-hydroxysuccinimide ester, poly(ethylene glycol)methyl ether(2-methyl-2-propionic acid dodecyl trithiocarbonate), poly(ethylene glycol)bis[2-(dodecylthiocarbonylthioylthio)-2-methylpropionate], 2-(dodecylthiocarbonylthioylthio)-2-methylpropionic acid 3-azido-1-propanol ester, 2-(dodecylthiocarbonylthioylthio)-2-methylpropionic acid pentafluorophenyl ester, poly(ethylene glycol)methyl ether 2-(dodecylthiocarbonylthiooylthio)-2-methylpropionate, poly(ethylene glycol)methyl ether 2-(dodecylthiocarbonylthiooylthio)-2-methylpropionate, poly(ethylene glycol)methyl ether 2-(dodecylthiocarbonylthiooylthio)-2-methylpropionate, poly(ethylene glycol)bis[2-(dodecylthiocarbonylthioylthio)-2-methylpropionate], and bis(dodecylsulfanylthiocarbonyl)disulphide; dithiocarbamates, such as benzyl 1H-pyrrole-1-carbodithioic acid, methyl 2-propionate methyl(4-pyridinyl)carbamodithioate, and N,N′-dimethyl N,N′-di(4-pyridinyl)thiuram disulfide; and xanthates. Among them, didithiobenzoate is preferred, and ethyl-2-(phenylcarbonothioylthio)propionate is more preferred. Only one of the chain transfer agents described above may be used, or two or more may be used.

The amount (total amount) of the chain transfer agent used is not particularly limited but is preferably from 0.001 to 100 mol, more preferably from 0.01 to 50 mol, even more preferably from 0.1 to 30 mol, and particularly preferably from 1 to 10 mol relative to the total amount (100 mol) of the monomers. In addition, the amount of the chain transfer agent used relative to the total amount of the monomers (100 parts by weight) is not particularly limited but is preferably from 0.1 to 100 parts by weight, more preferably from 0.5 to 50 parts by weight, and even more preferably from 1 to 25 parts by weight.

A well-known or commonly used polymerization initiator can be used as the polymerization initiator containing no cyano group, and examples include azo compounds containing no cyano group, such as dimethyl-2,2′-azobisisobutyrate, 2,2′-azobis(2,4,4-trimethylpentane), 2,2′-azobis(2-methylpropane), and dibutyl-2,2′-azobisisobutyrate. In addition, the examples include peroxide-based compounds containing no cyano group; such as ketone peroxides, such as methyl ethyl ketone peroxide and cyclohexanone peroxide; peroxyketals, such as 1,1-bis(tert-hexylperoxy)3,3,5-trimethylcyclohexane and 1,1-bis(tert-hexylperoxy)cyclohexane; hydroperoxides or dialkyl peroxides, such as P-menthane hydroperoxide and 2,5-dimethyl-2,5-bis(tert-butylperoxy)hexane; diacyl peroxides, such as isobutyryl peroxide and 3,3,5-trimethylhexanoyl peroxide; peroxy esters, such as 1,1,3,3-tetramethylbutylperoxy neodecanate and tert-hexylperoxy neodecanate; and peroxydicarbonates, such as di-n-propyl peroxydicarbonate and diisopropyl peroxydicarbonate. Furthermore, the examples include redox-based compounds containing no cyano group, such as hydrogen peroxide and ammonium persulfate.

Among them, azo compounds containing no cyano group are preferably used. Only one polymerization initiator may be used, or two or more may be used.

The amount (total amount) of the polymerization initiator used is any amount necessary to obtain a resin having a desired molecular weight distribution and is, for example, from 0.05 to 120 mol, preferably from 0.1 to 50 mol, and more preferably from 0.5 to 10 mol relative to the total amount (100 mol) of the monomers. In addition, the amount of the polymerization initiator used relative to the total amount (100 parts by weight) of the monomers is, for example, from 0.01 to 30 parts by weight, preferably from 0.2 to 20 parts by weight, and more preferably from 0.5 to 10 parts by weight. [0084]

The pKb of the basic compound A is the base dissociation constant of the solution at 25° C. when the solvent is water. The pKb of the basic compound A is not higher than 10 as described above, preferably not higher than 9, and more preferably not higher than 8. The lower limit of the pKb is, for example, 1.

Examples of the basic compound A include ammonia, amines (primary amines, such as allylamine, benzylamine, methylamine, ethylamine, n-propylamine, isopropylamine, n-butylamine, s-butylamine, t-butylamine, cyclohexylamine, cyclohexylmethylamine, ethanolamine, methoxyamine, hydrazine, ethylenediamine, and triethylenediamine; secondary amines, such as dimethylamine, diethylamine, di-n-propylamine, diisopropylamine, di-n-butylamine, diisobutylamine, t-butylcyclohexylamine, 2-methylpiperidine, and acetanilide; and tertiary amines, such as triethylamine, N,N-dimethylethylamine, N,N-diisopropylethylamine, tripropylamine, and 1-methylpiperidine), and nitrogen atom-containing heterocyclic compounds (such as pyridine, 1,8-diazabicyclo[5.4.0]undec-7-ene(diazabicycloundecene), 1,4-diazabicyclo[2.2.2]octane, 2-phenylimidazole, imidazole, and isoquinoline). Among them, tertiary amines and nitrogen atom-containing heterocyclic compounds are preferred. Only one basic compound A may be used, or two or more may be used.

The amount (total amount) of the basic compound A used is not particularly limited but is, for example, not less than 0.05 mol, preferably not less than 0.1 mol, and more preferably not less than 0.3 mol relative to the total amount (100 mol) of the monomers. The upper limit of the amount used is, for example, 10 mol, preferably 8 mol, and more preferably 5 mol.

The polymerization may be performed without a solvent or may be performed in the presence of a polymerization solvent. Examples of the polymerization solvent include glycol-based solvents (glycol-based compounds), ester-based solvents, ketone-based solvents, ether-based solvents, amide-based solvents, sulfoxide-based solvents, monohydric alcohol-based solvents (the monohydric alcohol-based compounds), hydrocarbon-based solvents, and their mixed solvents. Examples of the glycol solvent include propylene glycol monomethyl ether, propylene glycol monomethyl ether acetate, ethylene glycol monomethyl ether acetate, ethylene glycol monoethyl ether acetate, and ethylene glycol monobutyl ether acetate. Examples of the ester-based solvent include lactate ester-based solvents, such as ethyl lactate; propionate ester-based solvents, such as methyl 3-methoxypropionate; acetate ester-based solvents, such as methyl acetate, ethyl acetate, propyl acetate, and butyl acetate. Examples of the ketone-based solvent include acetone, methyl ethyl ketone, methyl isobutyl ketone, methyl amyl ketone, cyclopentanone, and cyclohexanone. Examples of the ether-based solvent include linear ethers, such as diethyl ether, diisopropyl ether, dibutyl ether, and dimethoxyethane; and cyclic ethers, such as tetrahydrofuran and dioxane. Examples of the amide-based solvent include N,N-dimethylformamide. Examples of the sulfoxide-based solvent include dimethyl sulfoxide. Examples of the hydrocarbon-based solvent include aliphatic hydrocarbons, such as pentane, hexane, heptane, and octane; alicyclic hydrocarbons, such as cyclohexane and methylcyclohexane; and aromatic hydrocarbons, such as benzene, toluene, and xylene.

Preferred polymerization solvent include glycol-based solvents, such as propylene glycol monomethyl ether and propylene glycol monomethyl ether acetate; ester-based solvents, such as ethyl lactate; ketone-based solvents, such as acetone, methyl ethyl ketone, methyl isobutyl ketone, methyl amyl ketone, cyclopentanone, and cyclohexanone; and their mixed solvents.

The dropwise addition of the solution containing a monomer may be continuous dropwise addition (an aspect of adding dropwise over a certain period of time) or may be intermittent dropwise addition (an aspect of adding dropwise dividedly in multiple times). In addition, the rate or the like of the dropwise addition may be changed one or more times during the dropwise addition.

The total dropwise addition time of the solution containing a monomer (the time from the start of the dropwise addition to the completion of the dropwise addition) varies with the polymerization temperature, the type of monomer, and the like but is typically from 1 to 10 hours, preferably from 2 to 9 hours, and even more preferably from 3 to 8 hours. The temperature of the solution containing a monomer to be added dropwise is preferably not higher than 40° C. The temperature of the solution containing a monomer not higher than 40° C. is more likely to prevent production of a polymer with too large molecular weight during the initial stage of the reaction. In addition, the solution containing a monomer, if excessively cooled, would crystallize depending on the type of monomer.

The polymerization temperature is not particularly limited but is, for example, from 30 to 150° C., preferably from 50 to 120° C., and more preferably from 60 to 100° C. The polymerization temperature may be changed one or more times within the range of the polymerization temperature described above during the polymerization.

The polymerization may include time for aging after completion of the dropwise addition. The time for aging is not particularly limited but is, for example, from 0.5 to 10 hours and preferably from 1 to 15 hours.

The polymer produced in the polymerization can be isolated by precipitation (including re-precipitation). For example, the target polymer can be obtained by adding a polymerization solution (polymer dope) into a solvent (precipitation solvent) to precipitate the polymer; or dissolving the polymer once again in an appropriate solvent, and adding the solution into a solvent (re-precipitation solvent) to re-precipitate the polymer; or alternatively adding a solvent (a re-precipitation solvent or a polymerization solvent) into a polymerization solution (polymer dope) to dilute the polymerization solution. The precipitation or re-precipitation solvent may be either an organic solvent or water and may be a mixed solvent. However, the isolation of the polymer in the polymerization is not mandatory, and the polymerization solution containing the polymer produced in the polymerization may be subjected as is to the treatment described later without isolation of the polymer from the polymerization solution.

As a solvent used as the precipitation or re-precipitation solvent, a well-known or commonly used solvent can be used. In addition, the organic solvent used as the precipitation or re-precipitation solvent may be an identical solvent to the polymerization solvent or may be a different solvent. Examples of the organic solvent used as the precipitation or re-precipitation solvent include organic solvents exemplified as the polymerization solvent (glycol-based solvents, ester-based solvents, ketone-based solvents, ether-based solvents, amide-based solvents, sulfoxide-based solvents, monohydric alcohol-based solvents, and hydrocarbon-based solvents); halogenated hydrocarbons (halogenated aliphatic hydrocarbons, such as methylene chloride, chloroform, and carbon tetrachloride; and halogenated aromatic hydrocarbons, such as chlorobenzene and dichlorobenzene); nitro compounds (such as nitromethane and nitroethane); nitriles (such as acetonitrile and benzonitrile); carbonates (such as dimethyl carbonate, diethyl carbonate, ethylene carbonate, and propylene carbonate); carboxylic acids (such as acetic acid); and mixed solvents containing these solvents.

Among them, the organic solvent used as the precipitation or re-precipitation solvent is preferably a solvent containing at least a hydrocarbon (in particular, an aliphatic hydrocarbon, such as hexane or heptane) or an alcohol (in particular, such as methanol, ethanol, propanol, isopropyl alcohol, or butanol). In such a solvent containing at least a hydrocarbon, the ratio of the hydrocarbon (e.g., an aliphatic hydrocarbon, such as hexane or heptane) and an additional solvent (e.g., esters, such as ethyl acetate) is, for example, the former/the latter (a volume ratio at 25° C.) of 10/90 to 99/1, preferably the former/the latter (a volume ratio at 25° C.) from 30/70 to 98/2, and more preferably the former/the latter (a volume ratio at 25° C.) from 50/50 to 97/3.

In addition, the organic solvent used as the precipitation or re-precipitation solvent is also preferably a mixed solvent of an alcohol (in particular, methanol) and water and a mixed solvent of a glycol-based solvent (in particular, polyethylene glycol) and water. The ratio (volume ratio at 25° C.) of the organic solvent (an alcohol or a glycol-based solvent) and water in such a case is, for example, the former/the latter (a volume ratio at 25° C.) from 10/90 to 99/1, preferably the former/the latter (a volume ratio at 25° C.) from 30/70 to 98/2, and more preferably the former/the latter (a volume ratio at 25° C.) from 50/50 to 97/3.

The polymer obtained by precipitation (including re-precipitation) is subjected as necessary to rinsing or a treatment of loosening and dispersing the polymer in a solvent under stirring to wash the polymer (which may be referred to as “repulping”). The polymer may be subjected to rinsing after repulping. Repulping or rinsing the polymer produced by the polymerization with a solvent can efficiently remove a residual monomer, a low molecular weight oligomer, or the like adhered to the polymer.

In the production method according to an embodiment of the present invention, the organic solvent used as the re-pulping or rinsing solvent is preferably, among others, a solvent containing at least a hydrocarbon (in particular, an aliphatic hydrocarbon, such as hexane or heptane), an alcohol (in particular, such as methanol, ethanol, propanol, isopropyl alcohol, or butanol), or an ester (in particular, such as ethyl acetate).

In the production method according to an embodiment of the present invention, the precipitation (including re-precipitation), repulping, or rinsing may be followed as necessary by decantation, filtration, or the like to remove the solvent, and drying treatment.

### Treatment

The treatment is to treat a resin end in the presence of an end treatment agent containing no cyano group, and examples include mixing the polymer obtained by the polymerization with an end treatment agent containing no cyano group (which may be hereinafter referred to as the “end treatment agent”). The mixing method is not particularly limited, and examples of the solvent used include those exemplified as the polymerization solvent in the polymerization. The method for producing the photoresist resin according to an embodiment of the present invention desirably includes the treatment in terms of improving the thermal stability of the resulting photoresist resin.

As the end treatment agent containing no cyano group, a compound similar to the compounds exemplified as the polymerization initiator containing no cyano group can be used. The end treatment agent and the polymerization initiator used may be identical or different. The amount of the end treatment agent used is not particularly limited but is, for example, from 5 to 1000 mol, preferably from 10 to 500 mol, and more preferably from 20 to 250 mol relative to the total amount (100 mol) of the monomers used in the polymerization. In addition, the amount of the end treatment agent used relative to the total amount (100 parts by weight) of the monomers is, for example, from 5 to 1000 parts by weight, preferably from 10 to 500 parts by weight, and more preferably from 20 to 250 parts by weight.

The stirring time for the mixed solution of the polymer and the end treatment agent is not particularly limited but is typically from 0.1 to 10 hours and preferably from 0.2 to 5 hours. The temperature of the mixed solution during the stirring is not particularly limited but is, for example, from 30 to 150° C., preferably from 50 to 120° C., and more preferably from 60 to 100° C.

The polymer produced in the treatment can be isolated by precipitation (including re-precipitation). As the isolation method, a method similar to those described in the polymerization can be employed. In addition, as the solvent used as the precipitation or re-precipitation solvent, those exemplified in the polymerization can be used. Furthermore, the polymer obtained by precipitation (including re-precipitation) is subjected as necessary to repulping. The polymer may be subjected to rinsing after repulping. As the organic solvent used as the repulping or rinsing solvent, those exemplified in the polymerization can be used. Moreover, the repulping or rinsing may be followed as necessary by decantation, filtration, or the like to remove the solvent, and drying treatment. The drying temperature is, for example, from 20 to 120° C. and preferably from 30 to 100° C. Drying is preferably performed under reduced pressure (e.g., not higher than 200 mmHg (26.6 kPa) and in particular not higher than 100 mmHg (13.3 kPa)).

### Photoresist Resin Composition

The photoresist resin composition according to an embodiment of the present invention contains at least the photoresist resin according to an embodiment of the present invention and a radiation-sensitive acid generator.

The radiation-sensitive acid generator is a compound composed of a nucleus and an acid to be generated, and a commonly used or well-known compound that efficiently generates an acid by exposure to a radiation, such as a visible light, an ultraviolet light, a far-ultraviolet light, an electron beam, or an X-ray, can be used. Examples of the nucleus include onium salt compounds, such as iodonium salts, sulfonium salts (including tetrahydrothiophenium salts), phosphonium salts, diazonium salts, and pyridinium salts; sulfonimide compounds; sulfone compounds; sulfonate ester compounds; disulfonyldiazomethane compounds; disulfonylmethane compounds; oxime sulfonate compounds; and hydrazine sulfonate compounds. In addition, examples of the acid to be generated by the exposure include alkyl or fluorinated alkyl sulfonic acids, alkyl or fluorinated alkyl carboxylic acids, and alkyl or fluorinated alkyl sulfonyl imide acids. Only one of them may be used, or two or more may be used.

The amount of the radiation-sensitive acid generator used can be appropriately selected according to the strength of the acid to be produced by the irradiation with the radiation, the ratio of each repeating unit in the photoresist resin, and the like and can be selected from a range from, for example, 0.1 to 30 parts by weight, preferably from 1 to 25 parts by weight, and even more preferably from 2 to 20 parts by weight relative to 100 parts by weight of the photoresist resin according to an embodiment of the present invention.

The photoresist resin composition can be prepared, for example, by mixing the photoresist resin and the radiation-sensitive acid generator in a solvent for a resist. As the solvent for a resist, solvents exemplified as the polymerization solvent, such as a glycol-based solvent, an ester-based solvent, a ketone-based solvent, and a mixed solvent of them, can be used.

The concentration of the photoresist resin according to an embodiment of the present invention in the photoresist resin composition is, for example, from 3 to 40 wt. %. The photoresist resin composition may contain an alkali-soluble component, such as an alkali-soluble resin (e.g., a novolac resin, a phenolic resin, an imide resin, and a carboxy group-containing resin); a colorant (e.g., a dye); or the like.

### Pattern Formation Method

The photoresist resin composition is applied onto a base material or a substrate and dried, and then the coating film (resist film) is exposed via a predetermined mask (or further baked after the exposure) to form a latent image pattern and then dissolved with an alkali, and thus a fine pattern can be formed with high precision.

Examples of the base material or the substrate include silicon wafers, metals, plastics, glasses, and ceramics. The application of the photoresist resin composition can be performed using a commonly used coating means, such as a spin coater, a dip coater, and a roller coater. The thickness of the coating film is, for example, from 0.05 to 20 μm and preferably from 0.1 to 2 μm.

For the exposure, a radiation, such as a visible light, an ultraviolet light, a far-ultraviolet light, an electron beam, or an X-ray, can be used.

An acid is produced from the radiation-sensitive acid generator through the exposure, and the acid quickly eliminates a protecting group (acid-decomposable group), such as a carboxy group, of a polymerization unit (repeating unit having an acid-decomposable group) that becomes alkali soluble by the action of the acid of the photoresist resin composition to produce a carboxy group or the like that contributes to solubilization. As a result, the predetermined pattern can be formed with good precision by development with an alkaline developer.

### EXAMPLES

Hereinafter, the present invention will be described in more detail based on examples, but the present invention is not limited by these examples. The weight average molecular weight (Mw) and the number average molecular weight (Mn) of the resin were determined by gel permeation chromatography (GPC) measurement using a tetrahydrofuran solvent. Polystyrene was used for a standard sample, and a refractometer (refractive index detector; RI detector) was used as a detector. In addition, the GPC measurement was performed using three columns connected in series, available from Showa Denko K.K. (“KF-806L (trade name)”), under conditions of a column temperature of 40° C., an RI temperature of 40° C., and a tetrahydrofuran flow rate of 0.8 mL/min. The molecular weight distribution (Mw/Mn) was calculated from the measurements.

### Example 1

To a round-bottom flask with a reflux tube, a stirring bar, and a three-way cock, 21.25 g of propylene glycol monomethyl ether acetate, 21.25 g of methyl ethyl ketone, 0.30 g (0.0013 mol) of dimethyl-2,2′-azobisisobutyrate (available from Wako Pure Chemical Industries, Ltd., “V-601 (trade name)”) as a polymerization initiator, and 3.15 g (0.0117 mol) of ethyl-2-methyl-2-phenylthiocarbonylthiopropionate were added under a nitrogen atmosphere, the temperature was kept at 80° C., and under stirring, a mixed solution of 18.81 g (0.076 mol) of 6-cyano-5-oxo-4-oxatricyclo[4.2.1.0^{3,7}]nonan-2-yl methacrylate, 4.91 g (0.019 mol) of 5,5-dioxo-4-oxa-5-thiatricyclo[4.2.1.0^{3,7}]nonan-2-yl methacrylate, 26.28 g (0.095 mol) of 1-(adamantan-1-yl)-1-methylpropyl methacrylate, 0.30 g (0.0013 mol) of dimethyl-2,2′-azobisisobutyrate as a polymerization initiator, 237 mg (2.34 mmol) of triethylamine, 120.42 g of propylene glycol monomethyl ether acetate, and 120.42 g of methyl ethyl ketone was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 31.55 g of the desired polymer was obtained.

A solution in which 31.55 g of the collected polymer was dissolved in 126.20 g of methyl ethyl ketone was charged in a round-bottom flask with a reflux tube, a stirring bar, and a three-way cock. The round-bottom flask was purged with nitrogen, then 34.05 g (0.15 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 30.24 g of the desired polymer was obtained. The collected polymer as analyzed by GPC had a weight average molecular weight (Mw) of 6000 and a molecular weight distribution (Mw/Mn) of 1.35. ¹³C NMR confirmed the absence of a peak at 126 ppm.

### Example 2

To a round-bottom flask with a reflux tube, a stirring bar, and a three-way cock, 27.33 g of propylene glycol monomethyl ether acetate, 18.22 g of methyl ethyl ketone, 0.400 g (0.0017 mol) of dimethyl-2,2′-azobisisobutyrate as a polymerization initiator, and 4.20 g (0.0156 mol) of ethyl-2-methyl-2-phenylthiocarbonylthiopropionate were added under a nitrogen atmosphere, the temperature was kept at 80° C., and under stirring, a mixed solution of 27.94 g (0.092 mol) of 2-(6-cyano-5-oxo-4-oxatricyclo[4.2.1.0^{3,7}]nonan-2-yloxy)-2-oxoethyl methacrylate, 2.40 g (0.010 mol) of 3-hydroxyadamantan-1-yl methacrylate, 11.11 g (0.061 mol) of 1-ethylcyclopentan-1-yl methacrylate, 8.55 g (0.041 mol) of 1-(cyclohexan-1-yl)-1-methylethyl methacrylate, 0.400 g (0.0017 mol) of dimethyl-2,2′-azobisisobutyrate as a polymerization initiator, 316 mg (3.13 mmol) of triethylamine, 109.33 g of propylene glycol monomethyl ether acetate, and 72.89 g of methyl ethyl ketone was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 29.89 g of the desired polymer was obtained.

A solution in which 29.89 g of the collected polymer was dissolved in 119.56 g of methyl ethyl ketone was charged in a round-bottom flask with a reflux tube, a stirring bar, and a three-way cock. The round-bottom flask was purged with nitrogen, then 43.03 g (0.19 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 28.72 g of the desired polymer was obtained. The collected polymer as analyzed by GPC had a weight average molecular weight (Mw) of 5800 and a molecular weight distribution (Mw/Mn) of 1.32. ¹³C NMR confirmed the absence of a peak at 126 ppm.

### Example 3

To a round-bottom flask with a reflux tube, a stirring bar, and a three-way cock, 44.32 g of propylene glycol monomethyl ether acetate, 0.600 g (0.0026 mol) of dimethyl-2,2′-azobisisobutyrate as a polymerization initiator, and 6.30 g (0.0235 mol) of ethyl-2-methyl-2-phenylthiocarbonylthiopropionate were added under a nitrogen atmosphere, the temperature was kept at 80° C., and under stirring, a mixed solution of 17.53 g (0.10 mol) of 2-oxotetrahydrofuran-3-yl methacrylate, 5.78 g (0.023 mol) of 3,5-dihydroxyadamantan-1-yl methacrylate, 21.01 g (0.080 mol) of 1-(adamantan-1-yl)-1-methylethyl methacrylate, 5.68 g (0.023 mol) of 2-ethyladamantan-2-yl methacrylate, 0.600 g (0.0026 mol) of dimethyl-2,2′-azobisisobutyrate as a polymerization initiator, 475 mg (4.69 mmol) of triethylamine, and 132.95 g of propylene glycol monomethyl ether acetate was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 31.02 g of the desired polymer was obtained.

A solution in which 31.02 g of the collected polymer was dissolved in 124.08 g of methyl ethyl ketone was charged in a round-bottom flask with a reflux tube, a stirring bar, and a three-way cock. The round-bottom flask was purged with nitrogen, then 67.01 g (0.29 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 30.57 g of the desired polymer was obtained. The collected polymer as analyzed by GPC had a weight average molecular weight (Mw) of 6300 and a molecular weight distribution (Mw/Mn) of 1.34. ¹³C NMR confirmed the absence of a peak at 126 ppm.

### Example 4

To a round-bottom flask with a reflux tube, a stirring bar, and a three-way cock, 27.33 g of propylene glycol monomethyl ether acetate, 18.22 g of propylene glycol monomethyl ether, 0.350 g (0.0015 mol) of dimethyl-2,2′-azobisisobutyrate as a polymerization initiator, and 3.67 g (0.0137 mol) of ethyl-2-methyl-2-phenylthiocarbonylthiopropionate were added under a nitrogen atmosphere, the temperature was kept at 80° C., and under stirring, a mixed solution of 17.79 g (0.080 mol) of 5-oxo-4-oxatricyclo[4.2.1.0^{3,7}]nonan-2-yl methacrylate, 10.10 g (0.040 mol) of 3,5-dihydroxyadamantan-1-yl methacrylate, 22.12 g (0.080 mol) of 1-(adamantan-1-yl)-1-methylpropyl methacrylate, 0.350 g (0.0015 mol) of dimethyl-2,2′-azobisisobutyrate as a polymerization initiator, 277 mg (2.74 mmol) of triethylamine, 109.33 g of propylene glycol monomethyl ether acetate, and 72.89 g of propylene glycol monomethyl ether was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 28.33 g of the desired polymer was obtained.

A solution in which 28.33 g of the collected polymer was dissolved in 113.32 g of methyl ethyl ketone was charged in a round-bottom flask with a reflux tube, a stirring bar, and a three-way cock. The round-bottom flask was purged with nitrogen, then 35.68 g (0.15 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 26.92 g of the desired polymer was obtained. The collected polymer as analyzed by GPC had a weight average molecular weight (Mw) of 7100 and a molecular weight distribution (Mw/Mn) of 1.36. ¹³C NMR confirmed the absence of a peak at 126 ppm.

### Example 5

To a round-bottom flask with a reflux tube, a stirring bar, and a three-way cock, 50.00 g of propylene glycol monomethyl ether acetate, 0.600 g (0.0026 mol) of dimethyl-2,2′-azobisisobutyrate as a polymerization initiator, and 6.30 g (0.0235 mol) of ethyl-2-methyl-2-phenylthiocarbonylthiopropionate were added under a nitrogen atmosphere, the temperature was kept at 80° C., and under stirring, a mixed solution of 15.17 g (0.892 mol) of 2-oxotetrahydrofuran-3-yl methacrylate, 4.95 g (0.022 mol) of 5-oxo-4-oxatricyclo[4.2.1.0^{3,7}]nonan-2-yl methacrylate, 5.26 g (0.022 mol) of 3-hydroxyadamantan-1-yl methacrylate, 24.62 g (0.089 mol) of 1-(adamantan-1-yl)-1-methylpropyl methacrylate, 0.600 g (0.0026 mol) of dimethyl-2,2′-azobisisobutyrate as a polymerization initiator, 475 mg (4.69 mmol) of triethylamine, and 132.95 g of propylene glycol monomethyl ether acetate was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 32.32 g of the desired polymer was obtained.

A solution in which 32.32 g of the collected polymer was dissolved in 129.28 g of methyl ethyl ketone was charged in a round-bottom flask with a reflux tube, a stirring bar, and a three-way cock. The round-bottom flask was purged with nitrogen, then 69.81 g (0.30 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 29.67 g of the desired polymer was obtained. The collected polymer as analyzed by GPC had a weight average molecular weight (Mw) of 6100 and a molecular weight distribution (Mw/Mn) of 1.15. ¹³C NMR confirmed the absence of a peak at 126 ppm.

### Example 6

To a round-bottom flask with a reflux tube, a stirring bar, and a three-way cock, 50.00 g of propylene glycol monomethyl ether acetate, 0.600 g (0.0026 mol) of dimethyl-2,2′-azobisisobutyrate as a polymerization initiator, and 6.30 g (0.0235 mol) of 1-(methoxycarbonyl)ethyl benzodithioate were added under a nitrogen atmosphere, the temperature was kept at 80° C., and under stirring, a mixed solution of 15.17 g (0.892 mol) of 2-oxotetrahydrofuran-3-yl methacrylate, 4.95 g (0.022 mol) of 5-oxo-4-oxatricyclo[4.2.1.0^{3,7}]nonan-2-yl methacrylate, 5.26 g (0.022 mol) of 3-hydroxyadamantan-1-yl methacrylate, 24.62 g (0.089 mol) of 1-(adamantan-1-yl)-1-methylpropyl methacrylate, 0.600 g (0.0026 mol) of dimethyl-2,2′-azobisisobutyrate as a polymerization initiator, 475 mg (4.69 mmol) of triethylamine, and 132.95 g of propylene glycol monomethyl ether acetate was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 31.89 g of the desired polymer was obtained.

A solution in which 31.89 g of the collected polymer was dissolved in 127.56 g of methyl ethyl ketone was charged in a round-bottom flask with a reflux tube, a stirring bar, and a three-way cock. The round-bottom flask was purged with nitrogen, then 68.88 g (0.30 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 29.23 g of the desired polymer was obtained. The collected polymer as analyzed by GPC had a weight average molecular weight (Mw) of 6300 and a molecular weight distribution (Mw/Mn) of 1.18. ¹³C NMR confirmed the absence of a peak at 126 ppm.

### Example 7

To a round-bottom flask with a reflux tube, a stirring bar, and a three-way cock, 27.33 g of propylene glycol monomethyl ether acetate, 18.22 g of propylene glycol monomethyl ether, 0.350 g (0.0015 mol) of dimethyl-2,2′-azobisisobutyrate as a polymerization initiator, and 3.29 g (0.0137 mol) of 1-(methoxycarbonyl)ethyl benzodithioate were added under a nitrogen atmosphere, the temperature was kept at 80° C., and under stirring, a mixed solution of 17.79 g (0.080 mol) of 5-oxo-4-oxatricyclo[4.2.1.0^{3,7}]nonan-2-yl methacrylate, 10.10 g (0.040 mol) of 3,5-dihydroxyadamantan-1-yl methacrylate, 22.12 g (0.080 mol) of 1-(adamantan-1-yl)-1-methylpropyl methacrylate, 0.350 g (0.0015 mol) of dimethyl-2,2′-azobisisobutyrate as a polymerization initiator, 277 mg (2.74 mmol) of triethylamine, 109.33 g of propylene glycol monomethyl ether acetate, and 72.89 g of propylene glycol monomethyl ether was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 27.56 g of the desired polymer was obtained.

A solution in which 27.56 g of the collected polymer was dissolved in 110.24 g of methyl ethyl ketone was charged in a round-bottom flask with a reflux tube, a stirring bar, and a three-way cock. The round-bottom flask was purged with nitrogen, then 34.72 g (0.15 mol) of dimethyl-2,2′-azobisisobutyrate as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 24.88 g of the desired polymer was obtained. The collected polymer as analyzed by GPC had a weight average molecular weight (Mw) of 7300 and a molecular weight distribution (Mw/Mn) of 1.23. ¹³C NMR confirmed the absence of a peak at 126 ppm.

### Comparative Example 1

To a round-bottom flask with a reflux tube, a stirring bar, and a three-way cock, 21.25 g of propylene glycol monomethyl ether acetate, 21.25 g of methyl ethyl ketone, 0.50 g (0.0030 mol) of azobisisobutyronitrile (“AIBN (trade name)” available from Wako Pure Chemical Industries, Ltd.) as a polymerization initiator, and 1.01 g (0.00456 mol) of 2-cyano-2-propyl benzothioate were added under a nitrogen atmosphere, the temperature was kept at 80° C., and under stirring, a mixed solution of 18.81 g (0.076 mol) of 6-cyano-5-oxo-4-oxatricyclo[4.2.1.0^{3,7}]nonan-2-yl methacrylate, 4.91 g (0.019 mol) of 5,5-dioxo-4-oxa-5-thiatricyclo[4.2.1.0^{3,7}]nonan-2-yl methacrylate, 26.28 g (0.095 mol) of 1-(adamantan-1-yl)-1-methylpropyl methacrylate, 0.50 g (0.0030 mol) of azobisisobutyronitrile (“AIBN (trade name)” available from Wako Pure Chemical Industries, Ltd.) as a polymerization initiator, 92.43 mg (0.913 mmol) of triethylamine, 120.42 g of propylene glycol monomethyl ether acetate, and 120.42 g of methyl ethyl ketone was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 37.90 g of the desired polymer was obtained.

A solution in which 37.90 g of the collected polymer was dissolved in 151.60 g of methyl ethyl ketone was charged in a round-bottom flask with a reflux tube, a stirring bar, and a three-way cock. The round-bottom flask was purged with nitrogen, then 11.36 g (0.069 mol) of azobisisobutyronitrile as an end treatment agent was added, the temperature was heated to 75° C. under stirring, and the mixture was reacted for 3 hours. After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 35.24 g of the desired polymer was obtained. The collected polymer as analyzed by GPC had a weight average molecular weight (Mw) of 5800 and a molecular weight distribution (Mw/Mn) of 1.35. ¹³C NMR confirmed the presence of a peak at 126 ppm.

### Comparative Example 2

The same operations as in Example 2 were performed with the exception that azobisisobutyronitrile was used as the end treatment agent in place of dimethyl-2,2′-azobisisobutyrate, and 28.95 g of a polymer was obtained. The collected polymer as analyzed by GPC had a weight average molecular weight (Mw) of 5900 and a molecular weight distribution (Mw/Mn) of 1.30. ¹³C NMR confirmed the presence of a peak at 126 ppm.

### Comparative Example 3

The same operations as in Example 3 were performed with the exception that azobisisobutyronitrile was used as the polymerization initiator in place of dimethyl-2,2′-azobisisobutyrate, and 30.72 g of a polymer was obtained. The collected polymer as analyzed by GPC had a weight average molecular weight (Mw) of 6400 and a molecular weight distribution (Mw/Mn) of 1.32. ¹³C NMR confirmed the presence of a peak at 126 ppm.

### Comparative Example 4

To a round-bottom flask with a reflux tube, a stirring bar, and a three-way cock, 27.33 g of propylene glycol monomethyl ether acetate, 18.22 g of propylene glycol monomethyl ether, 0.50 g (0.0022 mol) of dimethyl-2,2′-azobisisobutyrate, and 0.72 g (0.00325 mol) of 2-cyano-2-propyl benzothioate were added under a nitrogen atmosphere, the temperature was kept at 80° C., and under stirring, a mixed solution of 17.79 g (0.080 mol) of 5-oxo-4-oxatricyclo[4.2.1.0^{3,7}]nonan-2-yl methacrylate, 10.10 g (0.040 mol) of 3,5-dihydroxyadamantan-1-yl methacrylate, 22.12 g (0.080 mol) of 1-(adamantan-1-yl)-1-methylpropyl methacrylate, 0.50 g (0.0022 mol)] of dimethyl-2,2′-azobisisobutyrate as a polymerization initiator, 65.92 mg (0.651 mmol) of triethylamine, 109.33 g of propylene glycol monomethyl ether acetate, and 72.89 g of propylene glycol monomethyl ether was added dropwise at a constant rate over 6 hours. After completion of the dropwise addition, the reaction solution was continued to stir for another 2 hours.

After completion of the polymerization reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 28.96 g of the desired polymer was obtained.

A solution in which 28.96 g of the collected polymer was dissolved in 115.84 g of methyl ethyl ketone was charged in a round-bottom flask with a reflux tube, a stirring bar, and a three-way cock. The round-bottom flask was purged with nitrogen, then 8.67 g (0.038 mol) of dimethyl-2,2′-azobisisobutyrate as an end treatment agent was added, the temperature was heated to 75° C. under stirring, and the mixture was reacted for 3 hours.

After completion of the reaction, the reaction solution was added dropwise under stirring into a mixed liquid (25° C.) of heptane and ethyl acetate (8:2 in weight ratio), the amount of the mixed liquid being ten times the amount of the reaction solution. The resulting precipitate was filtered off and dried under reduced pressure, and 27.87 g of the desired polymer was obtained. The collected polymer as analyzed by GPC had a weight average molecular weight (Mw) of 7200 and a molecular weight distribution (Mw/Mn) of 1.30. ¹³C NMR confirmed the presence of a peak at 126 ppm.

### Comparative Example 5

The same operations as in Example 5 were performed with the exception that azobisisobutyronitrile was used as the end treatment agent in place of dimethyl-2,2′-azobisisobutyrate, and 28.95 g of a polymer was obtained. The collected polymer as analyzed by GPC had a weight average molecular weight (Mw) of 6200 and a molecular weight distribution (Mw/Mn) of 1.16. ¹³C NMR confirmed the presence of a peak at 126 ppm.

### Comparative Example 6

The same operations as in Example 6 were performed with the exception that azobisisobutyronitrile was used as the end treatment agent in place of dimethyl-2,2′-azobisisobutyrate, and 28.95 g of a polymer was obtained. The collected polymer as analyzed by GPC had a weight average molecular weight (Mw) of 6200 and a molecular weight distribution (Mw/Mn) of 1.18. ¹³C NMR confirmed the presence of a peak at 126 ppm.

### Comparative Example 7

The same operations as in Example 7 were performed with the exception that azobisisobutyronitrile was used as the end treatment agent in place of dimethyl-2,2′-azobisisobutyrate, and 28.95 g of a polymer was obtained. The collected polymer as analyzed by GPC had a weight average molecular weight (Mw) of 7200 and a molecular weight distribution (Mw/Mn) of 1.24. ¹³C NMR confirmed the presence of a peak at 126 ppm.

The resins produced in Example 1 and Comparative Example 1 above have polymerization units represented by formulas below.

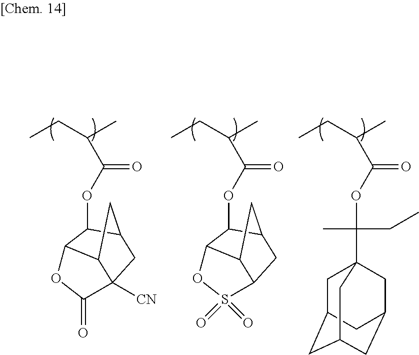

The resins produced in Example 2 and Comparative Example 2 above have polymerization units represented by formulas below.

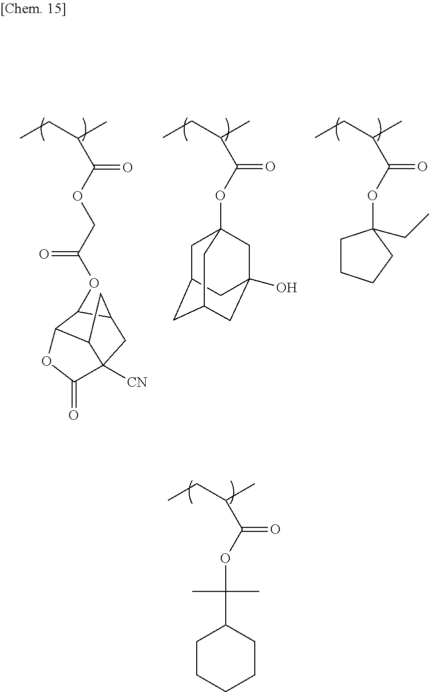

The resins produced in Example 3 and Comparative Example 3 above have polymerization units represented by formulas below.

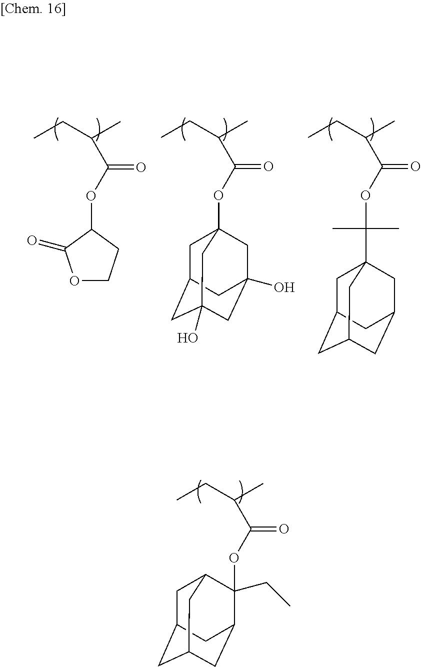

The resins produced in Example 4 and Comparative Example 4 above have polymerization units represented by formulas below.

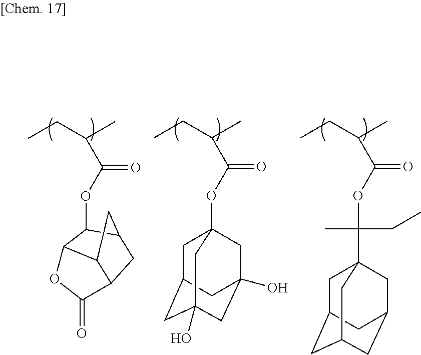

The resins produced in Examples 5 and 6 and Comparative Examples 5 and 6 above have polymerization units represented by formulas below.

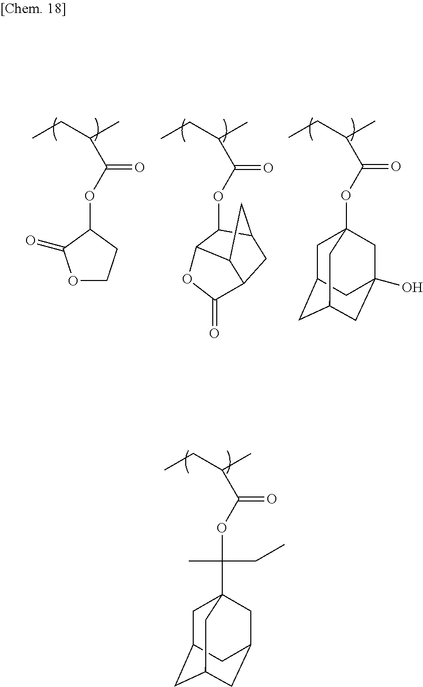

The resins produced in Example 7 and Comparative Example 7 above have polymerization units represented by formulas below.

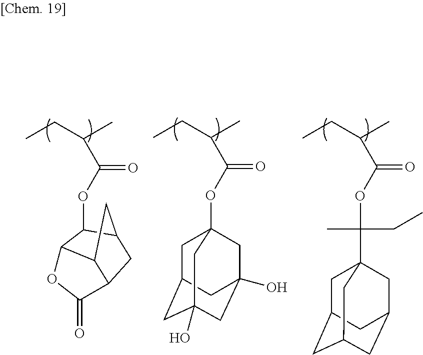

To each resin obtained in Examples 1 to 7 and Comparative Examples 1 to 7, PGMEA was added to make the resin concentration be 20 wt. %. At that time, the presence or absence of undissolved resin was visually checked to evaluate the solubility of the resin according to the following criteria. The results are shown in the section “resist performance” in Table 1.

Good: the solution is transparent, and no undissolved resin is visible.

Poor: undissolved resin is visible, or the solution shows white turbidity.

TABLE 1

| | | | | | | | | | | | | | Chain | | End | |
|---|---|---|---|---|---|---|---|---|---|---|---|---|---|---|---|---|
| | Monomer | | | | | | | | | | | | transfer | Polymerization | treatment | Resist |
| | A | B | C | D | E | F | G | H | I | J | K | L | agent | initiator | agent | performance |
| Example 1 | 40 | | | 10 | | | | | | 50 | | | R-1 | I-1 | I-1 | Good |
| Example 2 | | | 45 | | | 5 | | 30 | | | 20 | | R-1 | I-1 | I-1 | Good |
| Example 3 | | 45 | | | | | 10 | | 35 | | | 10 | R-1 | I-1 | I-1 | Good |
| Example 4 | | | | | 40 | | 20 | | | 40 | | | R-1 | I-1 | I-1 | Good |
| Example 5 | | 40 | | | 10 | 10 | | | | 40 | | | R-1 | I-1 | I-1 | Good |
| Example 6 | | 40 | | | 10 | 10 | | | | 40 | | | R-2 | I-1 | I-1 | Good |
| Example 7 | | | | | 40 | | 20 | | | 40 | | | R-2 | I-1 | I-1 | Good |
| Comparative | 40 | | | 10 | | | | | | 50 | | | R-3 | I-2 | I-2 | Poor |
| Example 1 | | | | | | | | | | | | | | | | |
| Comparative | | | 45 | | | 5 | | 30 | | | 20 | | R-1 | I-1 | I-2 | Poor |
| Example 2 | | | | | | | | | | | | | | | | |
| Comparative | | 45 | | | | | 10 | | 35 | | | 10 | R-1 | I-2 | I-1 | Poor |
| Example 3 | | | | | | | | | | | | | | | | |
| Comparative | | | | | 40 | | 20 | | | 40 | | | R-3 | I-1 | I-1 | Poor |
| Example 4 | | | | | | | | | | | | | | | | |
| Comparative | | 40 | | | 10 | 10 | | | | 40 | | | R-1 | I-1 | I-2 | Poor |
| Example 5 | | | | | | | | | | | | | | | | |
| Comparative | | 40 | | | 10 | 10 | | | | 40 | | | R-2 | I-1 | I-2 | Poor |
| Example 6 | | | | | | | | | | | | | | | | |
| Comparative | | | | | 40 | | 20 | | | 40 | | | R-2 | I-1 | I-2 | Poor |
| Example 7 | | | | | | | | | | | | | | | | |

The components shown in Table 1 are described below. In addition, the numerical value of each monomer shown in Table 1 is the molar amount (mol %) of each monomer relative to the total amount of the monomers (100 mol).

### Monomer

A: 6-Cyano-5-oxo-4-oxatricyclo[4.2.1.0^{3,7}]nonan-2-yl methacrylate

B: 2-Oxotetrahydrofuran-3-yl methacrylate

C: 2-(6-Cyano-5-oxo-4-oxatricyclo[4.2.1.0^{3,7}]nonan-2-yloxy)-2-oxoethyl methacrylate

D: 5,5-Dioxo-4-oxa-5-thiatricyclo[4.2.1.0^{3,7}]nonan-2-yl methacrylate

E: 5-Oxo-4-oxatricyclo[4.2.1.0^{3,7}]nonan-2-yl methacrylate

F: 3-Hy droxy adamantan-1-yl methacrylate

G: 3,5-Dihydroxyadamantan-1-yl methacrylate

H: 1-Ethylcyclopentan-1-ylmethacrylate

I: 1-(Adamantan-1-yl)-1-methylethyl methacrylate

J: 1-(Adamantan-1-yl)-1-methylpropyl methacrylate

K: 1-(Cyclohexan-1-yl)-1-methylethyl methacrylate

L: 2-Ethyladamantan-2-yl methacrylate

### Chain Transfer Agent

R-1: Ethyl-2-methyl-2-phenylthiocarbonylthiopropionate

R-2: 1-(Methoxycarbonyl)ethyl benzodithioate

R-3: 2-Cyano-2-propyl benzothioate

### Polymerization Initiator/end Treatment Agent

I-1: Dimethyl-2,2′-azobisisobutyrate

I-2: Azobisisobutyronitrile

As can be understood from the evaluation results, the photoresist resin according to an embodiment of the present invention (Examples 1 to 4) had excellent solubility in the solvent. Thus, the photoresist resin according to an embodiment of the present invention is expected to have excellent resist performance.

To summarize the above, configurations according to an embodiment of the present invention and their variations will be described below.

(1) A resin containing no cyano group at a resin end and having a molecular weight distribution (Mw/Mn) of not greater than 1.4.

(2) The resin according to (1), wherein a substituent at the resin end is an alkyl group, an aryl group, a carboxyl group, an amino group, a group having an ester bond, a group having an ether bond, a group having a thioether bond, or a group having an amide bond.

(3) The resin according to (1) or (2), obtained by polymerizing a monomer in the presence of a chain transfer agent containing no cyano group and containing a thiocarbonylthio group and a polymerization initiator containing no cyano group.

(4) The resin according to any one of (1) to (3), obtained by polymerizing a monomer in the presence of a chain transfer agent containing no cyano group and containing a thiocarbonylthio group and a polymerization initiator containing no cyano group, and then further treating in the presence of an end treatment agent containing no cyano group.

(5) The resin according to any one of (1) to (4), containing at least one polymerization unit selected from the group consisting of polymerization units represented by Formulas (a1) to (a4) above, where R represents a hydrogen atom, a halogen atom, or an alkyl group that has from 1 to 6 carbon atoms and may have a hydrogen atom; A represents a single bond or a linking group; R² to R⁴ are identical or different and represent an alkyl group that has from 1 to 6 carbon atoms and may have a substituent; R² and R³ may be bonded to each other to form a ring; R⁵ and R⁶ are identical or different and represent an alkyl group that has from 1 to 6 carbon atoms and may have a hydrogen atom or a substituent; R⁷ represents a —COOR^{c} group, and the R^{c} represents a tertiary hydrocarbon group that may have a substituent, a tetrahydrofuranyl group, a tetrahydropyranyl group, or an oxepanyl group; n represents an integer from 1 to 3; R^{a} represents a substituent bonded to a ring Zi, and each R^{a} is identical or different and is an oxo group, an alkyl group, a hydroxy group that may be protected with a protecting group, a hydroxyalkyl group that may be protected with a protecting group, or a carboxy group that may be protected with a protecting group; p represents an integer from 0 to 3; and the ring Zi represents an alicyclic hydrocarbon ring having from 3 to 20 carbon atoms.

(6) The resin according to (5), further containing at least one polymerization unit selected from the group consisting of polymerization units represented by Formulas (b1) to (b5) above, where R represents a hydrogen atom, a halogen atom, or an alkyl group that has from 1 to 6 carbon atoms and may have a hydrogen atom; A represents a single bond or a linking group; X represents no bond, a methylene group, an ethylene group, an oxygen atom, or a sulfur atom; Y represents a methylene group or a carbonyl group; Z represents a divalent organic group; V¹ to V³ are identical or different and represent —CH₂—, [—C(═O)—], or [—C(═O)—O—] with the proviso that at least one of V¹ to V³ is [—C(═O)—O—]; and R⁸ to R¹⁴ are identical or different and represent a hydrogen atom, a fluorine atom, an alkyl group that may have a fluorine atom, a hydroxy group that may be protected with a protecting group, a hydroxyalkyl group that may be protected with a protecting group, a carboxy group that may be protected with a protecting group, or a cyano group.

(7) The resin according to (5) or (6), further containing a polymerization unit represented by Formula (cl) above, where R represents a hydrogen atom, a halogen atom, or an alkyl group that has from 1 to 6 carbon atoms and may have a hydrogen atom; A represents a single bond or a linking group; R^{b} represents a hydroxy group that may be protected with a protecting group, a hydroxyalkyl group that may be protected with a protecting group, a carboxy group that may be protected with a protecting group, or a cyano group; q represents an integer from 1 to 5; and a ring Z² represents an alicyclic hydrocarbon ring having from 6 to 20 carbon atoms.

(8) The resin according to any one of (1) to (7), wherein a weight average molecular weight (Mw) is, for example, from 1000 to 50000, preferably from 2000 to 20000, and particularly preferably from 3000 to 15000.

(9) The resin according to any one of (1) to (8), wherein the molecular weight distribution (ratio of the weight average molecular weight and the number average molecular weight: Mw/Mn) is, for example, from 1.0 to 1.39 and preferably from 1.0 to 1.38.

(10) A method for producing the resin described in any one of (1) to (9), the method including polymerizing a monomer in the presence of a chain transfer agent containing no cyano group and containing a thiocarbonylthio group and a polymerization initiator containing no cyano group.

(11) The method for producing the resin according to (10), the method further including treating a resin end in the presence of an end treatment agent containing no cyano group.

(12) The resin according to any one of (3) to (9), wherein the chain transfer agent containing no cyano group and containing a thiocarbonylthio group is at least one selected from the group consisting of didithiobenzoates, such as 2-phenyl-2-propyl benzodithioate, 1-(methoxycarbonyl)ethyl benzodithioate, benzyl benzodithioate, ethyl-2-methyl-2-(phenylthiocarbonylthio)propionate, methyl-2-phenyl-2-(phenylcarbonothioylthio)acetate, ethyl-2-(phenylcarbonothioylthio)propionate, and bis(thiobenzoyl)disulfide; trithiocarbonates, such as 2-(dodecylthiocarbonylthioylthio)propionic acid, 2-(dodecylthiocarbonylthioylthio)-2-methylpropionic acid, methyl-2-(dodecylthiocarbonylthioylthio)-2-methylpropionate, 2-(dodecylthiocarbonylthioylthio)-2-methylpropionic acid N-hydroxysuccinimide ester, poly(ethylene glycol)methyl ether(2-methyl-2-propionic acid dodecyl trithiocarbonate), poly(ethylene glycol)bis[2-(dodecylthiocarbonylthioylthio)-2-methylpropionate], 2-(dodecylthiocarbonylthioylthio)-2-methylpropionic acid 3-azido-1-propanol ester, 2-(dodecylthiocarbonylthioylthio)-2-methylpropionic acid pentafluorophenyl ester, poly(ethylene glycol)methyl ether 2-(dodecylthiocarbonylthiooylthio)-2-methylpropionate, poly(ethylene glycol)methyl ether 2-(dodecylthiocarbonylthiooylthio)-2-methylpropionate, poly(ethylene glycol)methyl ether 2-(dodecylthiocarbonylthiooylthio)-2-methylpropionate, poly(ethylene glycol)bis[2-(dodecylthiocarbonylthioylthio)-2-methylpropionate], and bis(dodecylsulfanylthiocarbonyl)disulphide; dithiocarbamates, such as benzyl 1H-pyrrole-1-carbodithioic acid, methyl 2-propionate methyl(4-pyridinyl)carbamodithioate, and N,N′-dimethyl N,N′-di(4-pyridinyl)thiuram disulfide; and xanthates.

(13) The resin according to any one of (3) to (9), or (12), wherein the polymerization initiator containing no cyano group is at least one selected from the group consisting of azo compounds containing no cyano group, such as dimethyl-2,2′-azobisisobutyrate, 2,2′-azobis(2,4,4-trimethylpentane), 2,2′-azobis(2-methylpropane), and dibutyl-2,2′-azobisisobutyrate; peroxide compounds containing no cyano group, such as ketone peroxides (such as methyl ethyl ketone peroxide and cyclohexanone peroxide), peroxyketals (such as 1,1-bis(tert-hexylperoxy)3,3,5-trimethylcyclohexane and 1,1-bis(tert-hexylperoxy)cyclohexane), hydroperoxides or dialkyl peroxides (such as P-menthane hydroperoxide and 2,5-dimethyl-2,5-bis(tert-butylperoxy)hexane), diacyl peroxides (such as isobutyryl peroxide and 3,3,5-trimethylhexanoyl peroxide), peroxy esters (such as 1,1,3,3-tetramethylbutylperoxy neodecanate and tert-hexylperoxy neodecanate), and peroxydicarbonates (such as di-n-propyl peroxydicarbonate and diisopropyl peroxydicarbonate); and redox-based compounds containing no cyano group, such as hydrogen peroxide and ammonium persulfate.

(14) The resin according to any one of (3) to (9), (12), or (13), wherein the end treatment agent containing no cyano group is at least one selected from the group consisting of azo compounds containing no cyano group, such as dimethyl-2,2′-azobisisobutyrate, 2,2′-azobis(2,4,4-trimethylpentane), 2,2′-azobis(2-methylpropane), and dibutyl-2,2′-azobisisobutyrate; peroxide compounds containing no cyano group, such as ketone peroxides (such as methyl ethyl ketone peroxide and cyclohexanone peroxide), peroxyketals (such as 1,1-bis(tert-hexylperoxy)3,3,5-trimethylcyclohexane and 1,1-bis(tert-hexylperoxy)cyclohexane), hydroperoxides or dialkyl peroxides (such as P-menthane hydroperoxide and 2,5-dimethyl-2,5-bis(tert-butylperoxy)hexane), diacyl peroxides (such as isobutyryl peroxide and 3,3,5-trimethylhexanoyl peroxide), peroxy esters (such as 1,1,3,3-tetramethylbutylperoxy neodecanate and tert-hexylperoxy neodecanate), and peroxydicarbonates (such as di-n-propyl peroxydicarbonate and diisopropyl peroxydicarbonate); and redox-based compounds containing no cyano group, such as hydrogen peroxide and ammonium persulfate.

(15) The resin according to any one of (1) to (9) or (12) to (14), which is a photoresist resin

(16) A resin composition containing at least the resin described in any one of (1) to (9) or (12) to (14) and a radiation-sensitive acid generator.

(17) The resin composition according to (16), which is a photoresist resin composition.

(18) A pattern formation method including at least applying the composition described in (16) to a substrate to form a coating film, exposing the coating film, and then dissolving the coating film with an alkali.

### INDUSTRIAL APPLICABILITY

The photoresist resin according to an embodiment of the present invention and the production method according to an embodiment of the present invention can provide a photoresist resin having high solubility in solvents and excellent resist performance, and a photoresist resin composition containing the photoresist resin. In addition, use of the photoresist resin composition can form an excellent pattern.

1-9. (canceled)

10. A photoresist resin containing no cyano group at a resin end and having a molecular weight distribution (Mw/Mn) of not greater than 1.4.

11. The photoresist resin according to claim 10, wherein a substituent at the resin end is an alkyl group, an aryl group, a carboxyl group, an amino group, a group having an ester bond, a group having an ether bond, a group having a thioether bond, or a group having an amide bond.

12. The photoresist resin according to claim 10, obtained by polymerizing a monomer in the presence of a chain transfer agent containing no cyano group and containing a thiocarbonylthio group and a polymerization initiator containing no cyano group.

13. The photoresist resin according to claim 10, obtained by polymerizing a monomer in the presence of a chain transfer agent containing no cyano group and containing a thiocarbonylthio group and a polymerization initiator containing no cyano group, and then further treating in the presence of an end treatment agent containing no cyano group.

14. The photoresist resin according to claim 12, wherein the chain transfer agent containing no cyano group and containing a thiocarbonylthio group is at least one selected from the group consisting of di dithi ob enzoates, trithiocarbonates, dithiocarbamates, and xanthates.

15. The photoresist resin according to claim 12, wherein the polymerization initiator containing no cyano group is at least one selected from the group consisting of azo compounds containing no cyano group, peroxide compounds containing no cyano group, and redox-based compounds containing no cyano group.

16. The photoresist resin according to claim 12, wherein the end treatment agent containing no cyano group is at least one selected from the group consisting of azo compounds containing no cyano group, peroxide compounds containing no cyano group, and redox-based compounds containing no cyano group.

17. The photoresist resin according to claim 10, comprising at least one polymerization unit selected from the group consisting of polymerization units represented by Formulas (a1) to (a4) 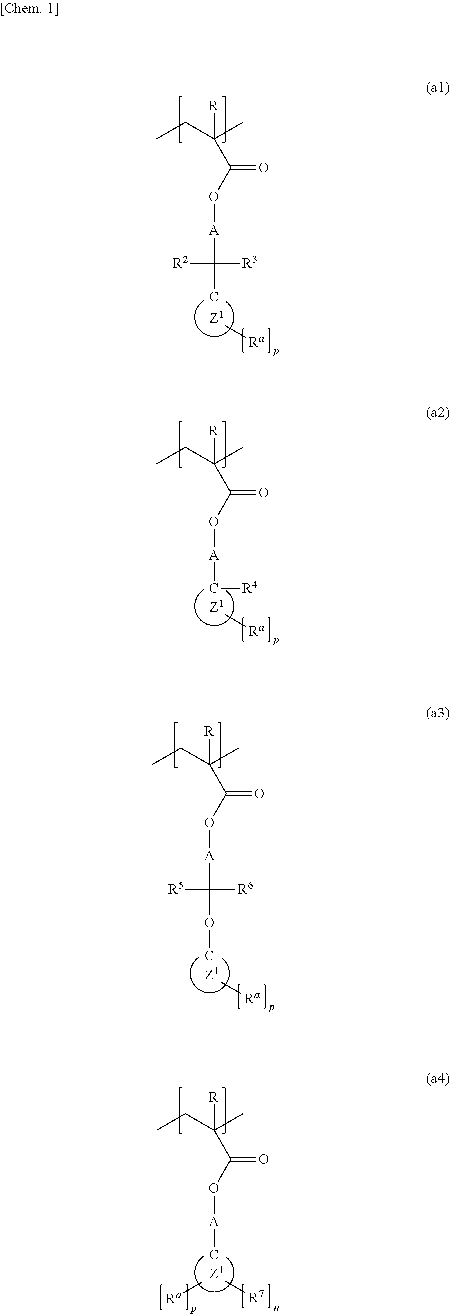
where R represents a hydrogen atom, a halogen atom, or an alkyl group that has from 1 to 6 carbon atoms and may have a hydrogen atom; A represents a single bond or a linking group; R² to R⁴ are identical or different and represent an alkyl group that has from 1 to 6 carbon atoms and may have a substituent, and R² and R³ may be bonded to each other to form a ring; R⁵ and R⁶ are identical or different and represent an alkyl group that has from 1 to 6 carbon atoms and may have a hydrogen atom or a sub stituent; R⁷ represents a —COOR^{c} group, and the R^{c} represents a tertiary hydrocarbon group that may have a substituent, a tetrahydrofuranyl group, a tetrahydropyranyl group, or an oxepanyl group; n represents an integer from 1 to 3; R^{a} represents a substituent bonded to a ring Z¹, and each R^{a} is identical or different and is an oxo group, an alkyl group, a hydroxy group that may be protected with a protecting group, a hydroxyalkyl group that may be protected with a protecting group, or a carboxy group that may be protected with a protecting group; p represents an integer from 0 to 3; and the ring Z¹ represents an alicyclic hydrocarbon ring having from 3 to 20 carbon atoms.

18. The photoresist resin according to claim 17, further comprising at least one polymerization unit selected from the group consisting of polymerization units represented by Formulas (b1) to (b5) 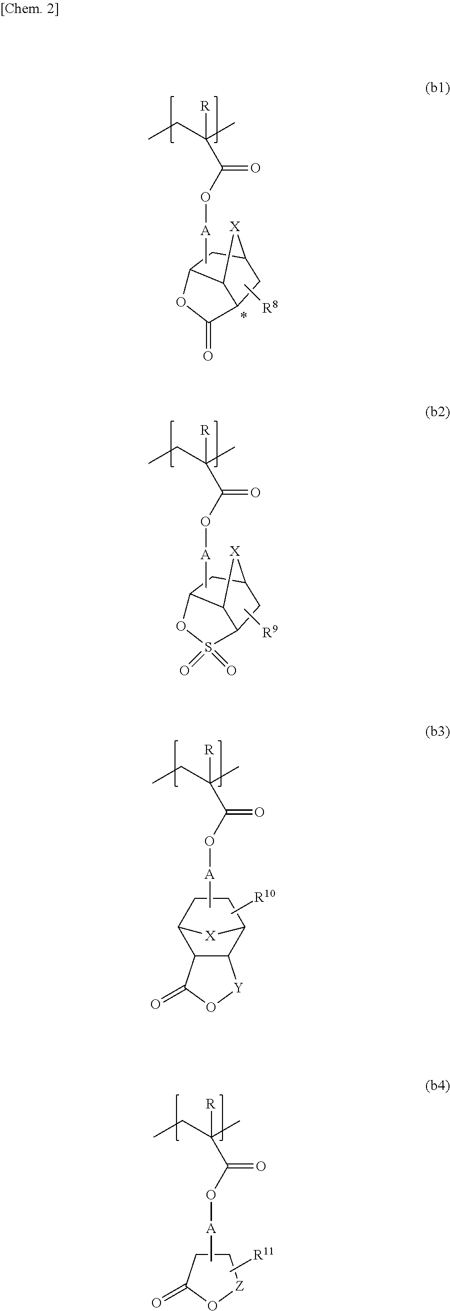 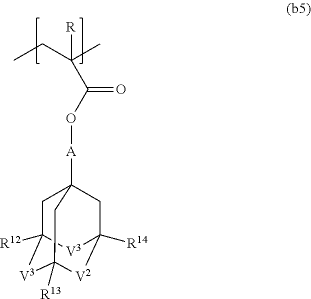
where R represents a hydrogen atom, a halogen atom, or an alkyl group that has from 1 to 6 carbon atoms and may have a hydrogen atom; A represents a single bond or a linking group; X represents no bond, a methylene group, an ethylene group, an oxygen atom, or a sulfur atom; Y represents a methylene group or a carbonyl group; Z represents a divalent organic group; V¹ to V³ are identical or different and represent —CH₂—, [—C(═O)—], or [—C(═O)—O—] with the proviso that at least one of V¹ to V³ is [—C(═O)—O—]; and R⁸ to R¹⁴ are identical or different and represent a hydrogen atom, a fluorine atom, an alkyl group that may have a fluorine atom, a hydroxy group that may be protected with a protecting group, a hydroxyalkyl group that may be protected with a protecting group, a carboxy group that may be protected with a protecting group, or a cyano group.

19. The photoresist resin according to claim 17, further comprising a polymerization unit represented by Formula (e1) 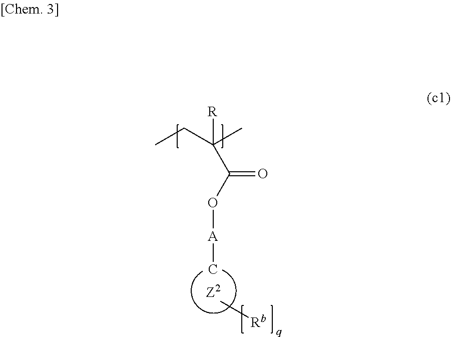
where R represents a hydrogen atom, a halogen atom, or an alkyl group that has from 1 to 6 carbon atoms and may have a hydrogen atom; A represents a single bond or a linking group; R^{b} represents a hydroxy group that may be protected with a protecting group, a hydroxyalkyl group that may be protected with a protecting group, a carboxy group that may be protected with a protecting group, or a cyano group; q represents an integer from 1 to 5; and a ring Z² represents an alicyclic hydrocarbon ring having from 6 to 20 carbon atoms.

20. The photoresist resin according to claim 10, wherein a weight average molecular weight (Mw) is from 1000 to 50000.

21. The photoresist resin according to claim 10, wherein the molecular weight distribution is from 1.0 to 1.39.

22. A method for producing the photoresist resin described in claim 10, the method comprising polymerizing a monomer in the presence of a chain transfer agent containing no cyano group and containing a thiocarbonylthio group and a polymerization initiator containing no cyano group.

23. The method for producing the photoresist resin according to claim 22, the method further comprising treating a resin end in the presence of an end treatment agent containing no cyano group.

24. The method for producing the photoresist resin according to claim 22, wherein the chain transfer agent containing no cyano group and containing a thiocarbonylthio group is at least one selected from the group consisting of didithiobenzoates, trithiocarbonates, dithiocarbamates, and xanthates.

25. The method for producing the photoresist resin according to claim 22, wherein the polymerization initiator containing no cyano group is at least one selected from the group consisting of azo compounds containing no cyano group, peroxide compounds containing no cyano group, and redox-based compounds containing no cyano group.

26. The method for producing the photoresist resin according to claim 22, wherein the end treatment agent containing no cyano group is at least one selected from the group consisting of azo compounds containing no cyano group, peroxide compounds containing no cyano group, and redox-based compounds containing no cyano group.

27. A photoresist resin composition comprising at least the photoresist resin described in claim 10 and a radiation-sensitive acid generator.

28. A pattern formation method comprising at least applying the photoresist resin composition described in claim 27 to a substrate to form a coating film, exposing the coating film, and then dissolving the coating film with an alkali.
